(19) United States
(12) Patent Application Publication
(10) Pub. No.: US 2025/0295043 A1
(43) Pub. Date: Sep. 18, 2025

(54) SUPERCONDUCTING QUANTUM CIRCUIT

(71) Applicant: NEC Corporation, Tokyo (JP)

(72) Inventors: Yohei KAWAKAMI, Tokyo (JP); Tsuyoshi YAMAMOTO, Tokyo (JP)

(73) Assignee: NEC Corporation, Tokyo (JP)

(21) Appl. No.: 19/071,842

(22) Filed: Mar. 6, 2025

(30) Foreign Application Priority Data
Mar. 15, 2024 (JP) 2024-041621

(51) Int. Cl. H10N 60/12; G06N 10/40

(52) U.S. Cl. CPC H10N 60/12; G06N 10/40

(57) ABSTRACT

A quantum circuit apparatus includes a coupler made up of one or more linear elements and at least three or more qubits coupled with a many-body interaction via the coupler, wherein at least one qubit out of the at least three or more qubits has a nonlinearity different from that of one or more other qubits.

### CROSS REFERENCE TO RELATED APPLICATIONS

This application is based upon and claims the benefit of the priority of Japanese patent application No. 2024-041621, filed on Mar. 15, 2024, the disclosure of which is incorporated herein in its entirety by reference thereto.

### FIELD

This disclosure relates to a superconducting quantum circuit.

### BACKGROUND

An LHZ (Lechner, Hauke, Zoller) scheme is known as one of quantum annealing schemes for solving combinatorial optimization problems (Reference Literature 1). Non-Patent Literature (NPL) 1 discloses a physical implementation of the LHZ scheme, with a network including quantum bits (qubits) and a coupler configured to couple four qubits with four-body interaction, as illustrated in FIG. 1 which is based on Figure a in FIG. 4 of NPL 1. In the example shown in FIG. 1, a Josephson Parametric Oscillator (JPO) is used as a qubit, and a nonlinear element such as a Josephson Junction (JJ) is used as a coupler.
[PTL 1] Puri, et. al., “Quantum annealing with all-to-all connected nonlinear oscillators”, Nature Communications 8, 15785 (2017)

### SUMMARY

To obtain a four-body interaction of sufficient magnitude for quantum annealing operation, for example,
a frequency difference between a resonance frequency of a qubit and a resonance frequency of the coupler;
nonlinearity of a coupler; and so on,
need to conform to a preset (desired) condition(s). As shown in FIG. 1, in a configuration using a nonlinear element such as a Josephson junction as a coupler, it is generally not easy to design and manufacture a coupler with a Josephson junction that satisfies the above conditions well. In addition, in a case of a frequency-variable coupler, time and man-hours are required for adjustment (calibration, etc.) thereof. In the frequency-variable coupler, a bias line used to adjust a frequency of the coupler and an input/output line used to read out a frequency of the coupler need to be provided. Furthermore, a measurement instrument(s) and wirings for connecting to the bias line and the input output line to the measurement instruments also need to be provided.

One of the purposes of the present disclosure is to provide a quantum circuit apparatus and a control method for a coupler enabled to implement a many-body interaction among multiple qubits, in which a strength of the many-body interaction can be configured to a desired value while eliminating need for a bias line and an input/output line for the coupler.

According to the present disclosure, the quantum circuit apparatus includes a coupler made up of one or more linear element; and at least three or more qubits configured to be coupled with a many-body interaction through the coupler, wherein at least one qubit of the at least three or more qubits is configured to have a nonlinearity different from that of one or more other qubits.

According to the present disclosure, a method of controlling a strength of coupling in which at least first to third qubits are coupled of many-body interaction through a coupler, wherein the coupler is configured of one or more linear elements and wherein at least one qubit among the first to third qubits is configured to have a nonlinearity different from that of one or more other qubits.

According to the present disclosure, with respect to a coupler through which qubits can be coupled with a many-body interaction, a bias line for frequency adjustment and an input/output line for reading out the frequency are not required, while a strength of the many-body interaction can be set to a desired value.

### BRIEF DESCRIPTION OF DRAWINGS

FIG. 1 is a diagram illustrating an example of a comparative example.

FIG. 2 is a diagram illustrating an example of a configuration of at least one of embodiments of the present disclosure.

FIG. 3 a is a diagram illustrating an example of the configuration of at least one of embodiments of the present disclosure.

FIG. 4 is a diagram illustrating another example of the configuration of at least one of embodiments of the present disclosure.

FIG. 5 is a diagram illustrating a configuration of at least one of embodiments of the present disclosure.

FIGS. 6A through 6D illustrate the configuration of at least one of embodiments of the present disclosure.

FIGS. 7A and 7B illustrate examples of qubits of at least one of embodiments of the present disclosure.

FIGS. 8A and 8B schematically illustrate an example layout of at least one of embodiments of the present disclosure.

FIG. 9 illustrates another example layout of at least one of embodiments of the present disclosure.

FIG. 10 illustrates another example of a configuration of at least one of embodiments of the present disclosure.

FIG. 11 is a diagram illustrating another example of a configuration of at least one of embodiments of the present disclosure.

FIG. 12 is a diagram illustrating an example of a configuration of at least one of embodiments of the present disclosure.

FIG. 13 is a diagram illustrating an example of a configuration of at least one of embodiments of the present disclosure.

FIG. 14 is a diagram illustrating an example of a configuration of at least one of embodiments of the present disclosure.

FIG. 15 is a diagram illustrating an example quantum computer of at least one of embodiments of the present disclosure.

### EXAMPLE EMBODIMENTS

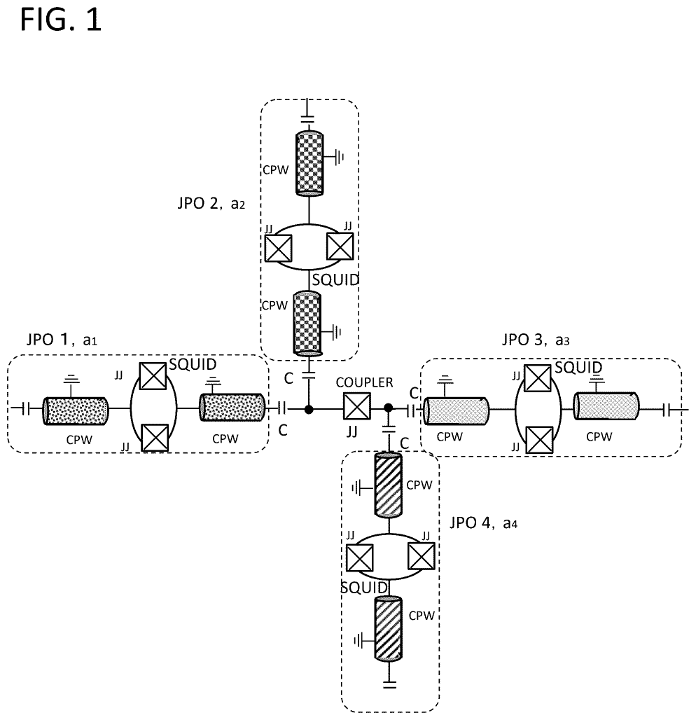

The following describes example embodiments of the present disclosure with reference to drawings. At the outset, a further analysis on the disclosure of FIG. 1 by the inventor of the present application is given below in relation to the issues described above. In FIG. 1, JPA (Josephson Parametric Amplifier) of NPL 1 is denoted as JPO because it functions as a parametric oscillator. Each of four qubits (JPO1 to JPO4) includes a SQUID (superconducting quantum interference device) with a loop in which multiple Josephson junctions (JJs) are arranged and is driven by a magnetic flux from an unshown magnetic field application unit. In the qubits (JPO1 to JPO4), Coplanar waveguides (CPWs) facing each other via the SQUID are an electrode/transmission line. In each qubit, an angular frequency of a pump signal ω_{p, i} (i=1, 2, 3, 4) is set close to 2 ωi: twice a resonance angular frequency ωi of the qubit. When a strength of a pump signal exceeds a threshold value, the qubit oscillates and outputs a signal with a resonance angular frequency ωi (called “parametric oscillation”).

In NPL 1, a condition for a four-body interaction of the four qubits (JPO1-JPO4) is that an angular frequency of each pump signal is set as follows, for example

$${ω}_{p} , 1 + {ω}_{p} , 2 = {ω}_{p} , 3 + {ω}_{p} 4 \qquad ( 1 )$$

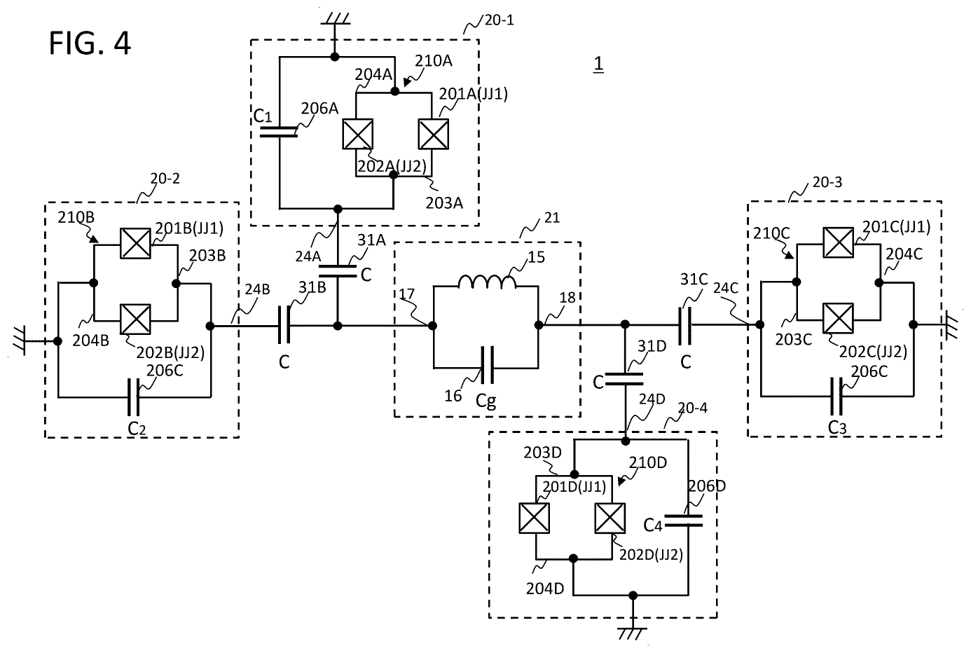

In NPL 1, a resonance angular frequency of the qubit is such that ωₖ≠ωₘ (k≠m, k, m=1, 2, 3, 4). In Equation (1), assuming that ω_{p, k}≠ω_{p, m} (k≠m, k, m=1, 2, 3, 4), when a difference between the angular frequency ω_{p, i}/2, which is one half of the pump frequency driving the qubit, and a resonant frequency ωi (i=1, 2, 3, 4) of the qubit is equal for all qubits, the resonant frequency of the qubits are detuned from each other. In FIG. 1, the four qubits (JPO1-JPO4) with different resonance angular frequencies are shown in different patterns according to FIG. 4 of NPL 1. As a condition for the four-body interaction (pump frequency condition) of the four qubits (JPO1-JPO4), besides Equation (1), the following conditions are also possible.

$${ω}_{p} , 1 + {ω}_{p} , 3 = {ω}_{p} , 2 + {ω}_{p} , 4 \qquad ( 1 - a )$$

$${ω}_{p} , 1 + {ω}_{p} , 4 = {ω}_{p} , 2 + {ω}_{p} , 3 \qquad ( 1 - b )$$

It is not necessary for all four qubits to be detuned with each other if only a four-body interaction occurs, but to avoid unnecessary two-body interaction, the resonant frequencies of the qubits must be detuned with each other when the difference between one-half the pump frequency and the resonant frequency is equal for all qubits.

In Equation (1), the coupler, in a rotational coordinate system, causes the following form of a coupling of the four-body interaction.

$${g}^{( 4 )} ( {a}_{1}^{†} {a}_{2}^{†} {a}_{3} {a}_{4} + {a}_{4}^{†} {a}_{3}^{†} {a}_{2} {a}_{1} ) \qquad ( 2 )$$

The coupling term of the four-body interaction in a Hamiltonian has a minus sign in Equation (2).
In Equation (2), aᵢ and aᵢ⁺ (i=1, 2, 3, 4) are annihilation and creation operators of a boson in each qubit, respectively. When conditions for the four-body interaction are in Equations. (1-a) and (1-b), respectively, the coupling of the four-body interaction in Equation (2) is expressed by the following Equations, respectively.

$${g}^{( 4 )} ( {a}_{1}^{†} {a}_{2} {a}_{3}^{†} {a}_{4} + {a}_{1} {a}_{2}^{†} {a}_{3} {a}_{4}^{†} ) \qquad ( 2 ‐ a )$$

$${g}^{( 4 )} ( {a}_{1}^{†} {a}_{2} {a}_{3} {a}_{4}^{†} + {a}_{1} {a}_{2}^{†} {a}_{3}^{†} {a}_{4} ) \qquad ( 2 ‐ b )$$

A strength of the four-body interaction (coupling coefficient) g⁽⁴⁾ is given as,

$${g}^{( 4 )} = {K}_{g} \frac{{g}_{1} {g}_{2} {g}_{3} {g}_{4}}{{Δ}_{1} {Δ}_{2} {Δ}_{3} {Δ}_{4}} \qquad ( 3 )$$

which depends on a nonlinearity of a Josephson junction (JJ) included in the coupler and a difference between a resonance frequency of each qubit and the coupler (detuning).

In Equation (3),
K_{g} is a nonlinear parameter (Kerr coefficient) of the coupler,
Δᵢ (i=1, 2, 3, 4) is a difference (detuning) between the resonance angular frequency ω_{c} of the coupler and the resonance angular frequency ωi of the i-th qubit (=ω_{c}−ωᵢ), and
gᵢ (i=1, 2, 3, 4) is a magnitude of coupling between the i-th qubit and the coupler.

From Equation (3), when the detuning Δᵢ is made as small as possible in a range of

$${g}_{i} / {Δ}_{i} < 1 ( i = 1 , 2 , 3 , 4 ) \qquad ( 4 )$$

the coupling coefficient of the four-body interaction g⁽⁴⁾ becomes large and the four-body interaction becomes strong. Therefore, the resonance angular frequency ωi (i=1, 2, 3, 4) of each qubit and the resonance angular frequency ωc of the coupler must be close to some extent.

In Equation (3), when approximating gᵢ/Δᵢ (i=1, 2, 3, 4) by g/Δ, the nonlinear parameter K_{g} of the coupler is multiplied by a quadrature term of g/Δ: (g/Δ)⁴.

From Equation (3), when the nonlinear parameter K_{g} of the coupler is increased, the coupling coefficient g⁽⁴⁾ of the four-body interaction becomes large. However, since the nonlinear parameter K_{g} of the coupler is multiplied by a power of 4: (g/Δ)⁴ less than 1, the coupling coefficient g⁽⁴⁾ of the four-body interaction is basically only a small value.

In a case where a Josephson junction is used as a fixed-frequency coupler, its resonance frequency depends on a critical current value of the Josephson junction, so it is necessary to fabricate a Josephson junction with a critical current value close to a desired value (design value).

On the other hand, in a case where the coupler is not a fixed-frequency type, but a frequency-variable type equipped with a SQUID, for example, an input/output lines for reading out a frequency of the coupler and a bias line for frequency change (adjustment) (e.g., a line to which a bias signal is fed to generate a bias magnetic flux to be applied to the SQUID). In addition to arranging these lines on a chip on which a network(s) of qubits and couplers are integrated, a wiring(s) and a cable(s) for measurement, a signal source(s), and a measurement instrument(s) are required outside the chip. Furthermore, a certain accuracy is required to adjust a difference in a resonance frequency between the coupler and the qubit.

Although the above issue is one example, the present disclosure enables a many-body interaction among a plurality of qubits in various situations, not limited to the above, and can contribute to simplify setting of a strength of a many-body interaction, i.e., a coupling coefficient.

According to the present disclosure, by using a coupler (also called a “linear coupler”) made up of one or linear elements (a linear circuit) for coupling among qubits, instead of a coupler including a nonlinear element such as a Josephson junction or a SQUID, as illustrated in FIG. 1, a design tolerance, frequency adjustment, calibration, etc. that are required when a nonlinear element is used for the coupler are reduced. A strength of the four-body interaction can be configured to a desired value based on a nonlinearity of each of the four qubits.

A linear element typically includes an inductor and a capacitor. However, in a case where a network of qubits and couplers is integrated on a wiring layer of a chip (such as a quantum chip or a wiring chip (interposer)), for example, a capacitance component between wires (such as between opposing electrodes or between an electrode and ground) constitutes a capacitor. In the present disclosure, for example, a linier element may include a circuit element patterned on a wiring layer of a chip, but does not necessarily include a discrete component or discrete device that may be arranged separate from the chip.

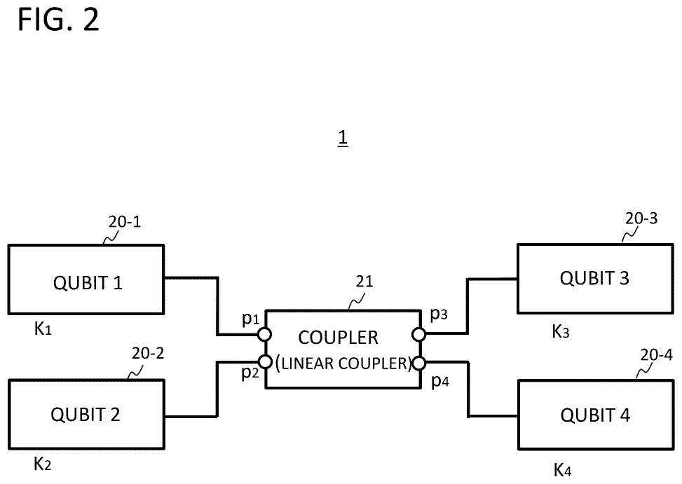

FIG. 2 schematically illustrates an example of the present disclosure. Referring to FIG. 2, a quantum circuit apparatus 1 includes first to fourth qubits 20-1 to 20-4, each of which is equipped with a nonlinear resonant circuit, and a coupler 21 configured to couple the fourth qubits 20-1 to 20-4 with a four-body interaction. Although FIG. 2 illustrates an example of four qubits coupled with a four-body interaction through the coupler 21, corresponding to FIG. 1, qubits may be coupled with a three-body interaction, a five-body interaction, or the like.

In FIG. 2, the first and second qubits 20-1 and 20-2 are connected to one end (first electrode) of the coupler 21 at ports 1 and 2 (p1 and p2), respectively, and the third and fourth qubits 20-3 and 20-4 are connected to the other end (second electrode) of the coupler 21 at ports 3 and 4 (p3, p4), respectively. The first and second qubits 20-1 and 20-2 are capacitively coupled to one end of the coupler 21 at the ports 1 and 2 (p1, p2), and the third and fourth qubits 20-3 and 20-4 are connected to the other end of the coupler 21 at the ports 3, 4 (p3, p4), and the third and fourth qubits 20-3, 20-4 may be capacitively coupled to the other end of the coupler 21 at ports 3, 4 (p3, p4). Alternatively, the first and second qubits 20-1 and 20-2 may be wired directly (DC coupled) to one end of the coupler 21 at the ports 1 and 2 (p1 and p2), respectively, and the third and fourth qubits 20-3 and 20-4 may be capacitively coupled to the other end of the coupler 21 at the ports 3 and 4, respectively. The third and fourth qubits 20-3 and 20-4 may be wired directly (DC coupled) to the other end of the coupler 21 at ports 3 and 4 (p3 and p4), respectively.

The coupler 21 includes a capacitor, an inductor, or a parallel resonant circuit made up of an inductor and a capacitor, as a linear element(s) connected between the first and second electrodes.

Each of the first to fourth qubits 20-1 to 20-4 may be configured to include at least one Josephson junction and a capacitor (shunt capacitor) connected in parallel between an electrode and ground.

Each of the first to fourth qubits 20-1 to 20-4 may include at least one SQUID and a capacitor (shunt capacitor) connected in parallel between the electrode and ground.

In FIG. 2, K₁ to K₄ attached to the first to fourth qubits 20-1 to 20-4, respectively, represent nonlinear parameters of the first to fourth qubits 20-1 to 20-4. In the following, as a condition for the four-body interaction of the first to the fourth qubits 20-1 to 20-4, with respect to each resonance angular frequency ωᵢ (i=1, 2, 3, 4), a difference between one-half of the pump frequency ω_{p, i} (i=1, 2, 3, 4) and the resonance angular frequency is equal to each other for the first to the fourth qubits 20-1 to 20-4, in correspondence with Equation (1),

$${ω}_{1} + {ω}_{2} = {ω}_{3} + {ω}_{4} \qquad ( 5 )$$

shall be satisfied. The first to fourth qubits 20-1 to 20-4 may be detuned from each other.

In the present disclosure, preferably, at least one of the nonlinear parameters K₁-K₄ of the first to fourth qubits 20-1 to 20-4 is set to a value different from each other.

For example, the absolute value of a difference |K₁−K₂| between the nonlinear parameters K₁ and K₂ of the first qubit 20-1 and the second qubit 20-2 and an absolute value |K₃−K₄| of a difference between the nonlinear parameters K₃ and K₄ of the third qubit 20-3 and the fourth qubit 20-4 are both set large, and a difference (δ₁₂=ω₁−ω₂) between the resonance angular frequency of the first qubit 20-1 ω₁, and that of the second qubit 20-2 ω₂, a difference (δ₃₄=ω₃−ω₄) between the resonance angular frequency ω₃ of the third qubit 20-3 and the resonance angular frequency ω₄ of the fourth qubit 20-4 may be adjusted to set the four-body interaction among the first and fourth qubits 20-1 to 20-4. For example, the four-body interaction among the first and fourth qubits 20-1 to 20-4 may be set to be strengthened by setting both the absolute values of the difference in resonance frequencies |δ₁₂| and |δ₃₄| to be large.

Alternatively, the four-body interaction among the first and fourth qubits 20-1 to 20-4 may be set to be strengthened by making one of |K₁−K₂| and |K₃−K₄| larger and the other smaller. Here, based on the condition of the four-body interaction, Equation (5), in the pairs of nonlinear parameters K₁ and K₂ for the first qubit 20-1 and the second qubit 20-2, and the nonlinear parameters of K₃ and K₄ for the third qubit 20-3 and the fourth qubit 20-4, values of the nonlinear parameters are shifted, but corresponding to the condition for the four-body interaction, a combination for the nonlinear parameters that make the four-body interaction stronger, may be different from the above.

As a condition for the four-body interaction of the first to the fourth qubits 20-1 to 20-4, for each resonance angular frequency ωi (i=1, 2, 3, 4), the difference between one-half of the pump frequency ω_{p, i} (i=1, 2, 3, 4) and the resonance angular frequencies are all When they are equal to each other in qubit, e.g., corresponding to Equation (1-a),

$${ω}_{1} + {ω}_{3} = {ω}_{2} + {ω}_{4} \qquad ( 6 )$$

then an absolute value |K₁−K₃| of a difference between the nonlinear parameters K₁ and K₃ of the first and third qubits 20-1 and 20-3 and the absolute value |K₂−K₄| of a difference between the second and fourth qubits 20-2 and 20-4 are both set large, and a difference between the resonance angular frequency of the first qubit 20-1 ω₁, and that of the third qubit 20-3 ω₃ (δ₁₃=ω₁−ω₃), a difference between the resonance angular frequency ω₂ of the second qubit 20-2 and that of the fourth qubit 20-4 ω₄ (δ₂₄=ω₂−ω₄) may be adjusted to set the four-body interaction among the first and fourth qubits 20-1 to 20-4.

As a condition for the four-body interaction of the first to the fourth qubits 20-1 to 20-4, for each resonance angular frequency ωi (i=1, 2, 3, 4), the difference between one-half of the pump frequency ω_{p, i} (i=1, 2, 3, 4) and the resonance angular frequencies are all when they are equal to each other in qubit, e.g., corresponding to Equation (1-b),

$${ω}_{1} + {ω}_{4} = {ω}_{2} + {ω}_{3} \qquad ( 7 )$$

then an absolute value |K₁−K₄| of a difference between the nonlinear parameters K₁ and K₄ of the first and fourth qubits 20-1 and 20-4 and the absolute value |K₂−K₃| of a difference between the second and third qubits 20-2 and 20-3 are both set large, and a difference between the resonance angular frequency of the first qubit 20-1 ω₁, and that of the fourth qubit 20-4 ω₄ (δ₁₄=ω₁−ω₄), a difference between the resonance angular frequency ω₂ of the second qubit 20-2 and that of the third qubit 20-3 ω₃ (δ₂₃=ω₂−ω₃) may be adjusted to set the four-body interaction among the first and fourth qubits 20-1 to 20-4.

The four-body interaction due to the nonlinearity of the qubits 20 may also be canceled (turned off) by setting K1−K4 of the first to fourth qubits 20-1 to 20-4 to be identical or by adjusting the difference in resonance frequency of the two qubits 20. However, when the difference between the one half of the pump frequency and the resonance angular frequency differs in even one qubit, the four body interaction is not necessarily canceled out.

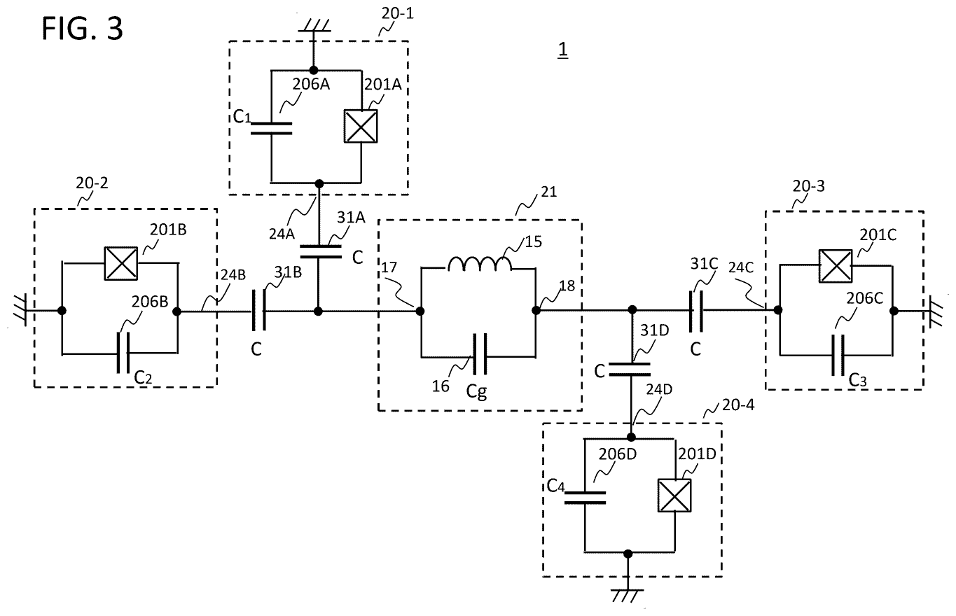

FIG. 3 illustrates an example of at least one of example embodiments of the present disclosure. FIG. 3 schematically illustrates an example of a quantum circuit apparatus 1 in which the qubit 20 is a superconducting qubit. Referring to FIG. 3, the first qubit 20-1 includes a Josephson junction 201A and a capacitor 206A connected in parallel between n an electrode 24A and ground. The electrode 24A of the first qubit 20-1 is capacitively coupled to a first electrode 17 (first node) of the coupler 21 via a coupling capacitor 31A. The electrode 24A may include a connection portion (coupler connection) that capacitively couples to the first electrode 17 of the coupler 21. A second qubit 20-2 includes a Josephson junction 201B and a capacitor 206B connected in parallel between an electrode 24B and ground. The electrode 24B of the second qubit 20-2 is capacitively coupled to the first electrode 17 (first node) of the coupler 21 via a coupling capacitor 31B. The electrode 24B may include a connection portion (coupler connection) that capacitively couples to the first electrode 17 of the coupler 21. A third qubit 20-3 includes a Josephson junction 201C and a capacitor 206C connected in parallel between an electrode 24C and ground. The electrode 24C of the third qubit 20-3 is capacitively coupled to a second electrode 18 (second node) of the coupler 21 via a coupling capacitor 31C. The electrode 24C may include a connection portion (coupler connection) that capacitively couples to the second electrode 18 of the coupler 21. A fourth qubit 20-4 includes a Josephson junction 202D and a capacitor 206D connected in parallel between an electrode 24D and ground. The electrode 24D of the fourth qubit 20-4 is capacitively coupled to the second electrode 18 (second node) via a coupling capacitor 31D. The electrode 24D may include a connection portion (coupler connection) that capacitively couples to the second electrode 18 of the coupler 21. In the following, when individual qubits are not identified for the first to fourth qubits 20-1 to 20-4, a branch number is removed and the qubit is simply denoted as qubit 20, and the same may be applied for the Josephson junction 201, capacitor 206, etc.

In the coupler 21, a parallel resonant circuit made up of an inductor 15 and a capacitor 16 is connected between the first electrode 17 and the second electrode 18. The first electrode 17 and the second electrode 18 are spaced apart and opposite each other in the coupler 21. The first electrode 17 may include first and second connection portions (not shown) capacitively coupled to the electrodes 24A and 24B of the first and second qubits 20-1 and 20-2, respectively. The second electrode 18 may include third and fourth connection portions (not shown) capacitively coupled with the electrodes 24C and 24D of the third and fourth qubits 20-3 and 20-4, respectively.

In FIG. 3, the qubit 20, which includes a parallel circuit of the Josephson junction 201 and the capacitor 206 is fixed in a resonant frequency. The qubit 20 may be configured as a frequency-variable qubit including a parallel circuit of a SQUID and a capacitor (shunt capacitor), as illustrated in FIG. 4. Referring to FIG. 4, in the quantum circuit apparatus 1, the first qubit 20-1 includes a superconducting member 203A, a Josephson junction 201A, a superconducting member 204A, a Josephson junction 202A configured as a loop. The superconducting member 203A is connected to the electrode 24A, the superconducting member 204A is connected to ground, and a capacitor 206A (shunt capacitor) is connected in parallel to the SQUID 210A between electrode 24A and ground. In operation, a magnetic flux is generated through the SQUID 210A by feeding a current through an unshown inductor, and by varying the magnetic flux, a resonance angular frequency ω₁ of the first qubit 20-1 can be varied. In the second through fourth qubits 20-2 to 20-4, respectively, the superconducting members 203B to 203D correspond to the superconducting member 203A of the first qubit 20-1, Josephson junctions 201B-201D correspond to Josephson junction 201A of the first qubit 20-1, the superconducting members 204B to 204D correspond to the superconducting member 204A of the first qubit 20-1, Josephson junctions 202B-202D correspond to Josephson junction 202A of the first qubit 20-1, SQUIDs 210B-210D correspond to SQUID 210A of the first qubit 20-1, and capacitors 206B-206D correspond to the capacitor 206A of the first qubit 20-1.

In embodiments of the present disclosure, a four-body interaction among four qubits arises from a nonlinearity of each qubit 20, not the coupler 21. Referring again to FIG. 2, the coupling coefficient h⁽⁴⁾ of the four-body interaction arising from a nonlinearity of each of the first to fourth qubits 20-1 to 20-4 can be expressed, for example, as follows.

$${h}^{( 4 )} = 2 {\sum }_{i = 1}^{4} {{\prod }_{j = 1}^{4}}_{( j \neq i )} [ ( \frac{{h}_{i j}}{{δ}_{j i}} ) {K}_{i} ] \qquad ( 8 )$$

In Equation (8),
hᵢⱼ (i, j=1, 2, 3, 4 (j≠i)) represents a strength (magnitude) of the coupling between the j-th qubit 20-i and the i-th qubit 20-j (also called “coupling constant”),
δⱼᵢ (i, j=1, 2, 3, 4 (j≠i)) is the difference ωⱼ−ωᵢ between the resonance angular frequency ωⱼ of the j-th qubit 20-j and the resonance angular frequency ωᵢ of the i-th qubit 20-i, and
Kᵢ (i=1, 2, 3, 4) is a parameter (Kerr coefficient) representing a nonlinear of the i-th qubit 20-i.

Here, in Equation (8), with respect to the multiplication term:

$${{\prod }_{j = 1}^{4}}_{( j \neq i )} ( \frac{{h}_{i j}}{{δ}_{j i}} ) {K}_{i}$$

letting hᵢⱼ (j=1, 2, 3, 4 (j≠i)) be h and δⱼᵢ (j=1, 2, 3, 4 (j≠i)) be δ, and let K_{q} be an effective value of hᵢⱼ/δⱼᵢ including its sign (effective Kerr coefficient that remains after being canceled by sign ±), can be expressed as follows.

$${( \frac{h}{δ} )}^{3} {K}_{q} \qquad ( 9 )$$

In Expression (9), the following holds.

$$\frac{h}{δ} < 1 \qquad ( 10 )$$

With this condition, by making the difference in resonance angular frequency δ between the two qubits (i-th and j-th qubits 20-i and 20-j) as small as possible, a value that Expression (9) takes becomes large.

From Expression (9), by setting the parameter K_{q}, which represents the nonlinearity of the qubit 20, large, it is also possible to make the coefficient h⁽⁴⁾ of the four-body interaction large.

In Equation (3), the coupler nonlinearity parameter (Kerr coefficient) K_{g} is multiplied by the fourth power term (g/Δ)⁴ of (g/Δ) (<1) as the coefficient g⁽⁴⁾ of the four-body interaction. For example, as an example disclosed in NPL 1, if g/Δ˜0.12, then (g/Δ)⁴˜0.00021.

On the other hand, in Expression (9), the nonlinear parameter K_{q} of the qubit 20 is multiplied by the cubic term (h/δ)³ of (h/δ) (<1). Therefore, the coupling coefficient h⁽⁴⁾ of the four-body interaction due to the nonlinearity of the qubit 20 is relatively easy to be made large as compared with g⁽⁴⁾ in Equation (3). The coupling coefficient h⁽⁴⁾ can be nearly by one order of magnitude larger than g⁽⁴⁾ in Equation (3) when K_{q} and K_{g} are of the same order, for example.

In addition, a degree of freedom of the coupler 21 (a parameter associated with the coupler 21) are not involved in Equation (8), which represents the four-body interaction due to the nonlinearity of the qubits 20. Therefore, there is no need to adjust a resonance frequency of the coupler 21 to strengthen the four-body interaction. That is, the coupler 21 does not need to include nonlinear element such as a Josephson junction(s) and a SQUID(s), but can be made up of one or more linear elements. When the coupler 21 is made up of one or more linear elements, there is no need to arrange a signal source to vary a frequency of the coupler 21, a control line(s) and an input/output line(s), or a measurement equipment(s). A degree of freedom of the coupler 21 (a parameters associated with the coupler 21) is not involved in Equation (8) which represents the four-body interaction, but this does not preclude the coupler 21 from being made up of a nonlinear element(s). In a case where the coupler can generate any interaction including a four-body interaction (e.g., as defined in Equation (3)), the four-body interaction expressed in Equation (8) can coexist therewith.

In Equation (8), focusing on i=1, i.e. the first qubit 20-1 in FIG. 2, the multiplication term regarding:
δ₂₁ (=ω₂−ω₁): the difference in resonance angular frequency between the second qubit 20-2 and the first qubit 20-1, and the coupling strength between the first qubit 20-1 and the second qubit 20,
δ₃₁ (=ω₃−ω₁): the difference in resonance angular frequency between the third qubit 20-3 and the first qubit 20-1,
h₁₃: the coupling strength between the first qubit 20-1 and the third qubit 20-3,
δ₄₁ (=ω₄−ω₁): the difference in resonance angular frequency between the fourth qubit 20-4 and the first qubit 20-1,
h₁₄: the coupling strength between the first qubit 20-1 and the fourth qubit 20-4, a multiplication term for i=1 in Equation (8) with respect to the strength of the coupling between the first qubit 20-1 and the fourth qubit 20-4, is given as follows.

$$( \frac{{h}_{12}}{{δ}_{21}} ) ( \frac{{h}_{13}}{{δ}_{31}} ) ( \frac{{h}_{14}}{{δ}_{41}} ) {K}_{1} \qquad ( 11 )$$

Equation (9) is a generalization of Equation (11).

When expanding Equation (8) for the first to fourth qubits 20-1 to 20-4 of FIG. 2, we have the following Equation (12).

$${h}^{( 4 )} = 2 ( {K}_{1} \frac{{h}_{21}}{{δ}_{21}} \frac{{h}_{31}}{{δ}_{31}} \frac{{h}_{41}}{{δ}_{41}} + {K}_{2} \frac{{h}_{12}}{{δ}_{12}} \frac{{h}_{32}}{{δ}_{32}} \frac{{h}_{42}}{{δ}_{42}} + {K}_{3} \frac{{h}_{13}}{{δ}_{13}} \frac{{h}_{23}}{{δ}_{23}} \frac{{h}_{43}}{{δ}_{43}} + {K}_{4} \frac{{h}_{14}}{{δ}_{14}} \frac{{h}_{24}}{{δ}_{24}} \frac{{h}_{34}}{{δ}_{34}} ) \qquad ( 12 )$$

In Equation (12), the condition for the four-body interaction are assumed as below.

$${ω}_{1} + {ω}_{2} = {ω}_{3} + {ω}_{4} \qquad ( 13 )$$

From Equation (13).

$${ω}_{3} - {ω}_{1} = - ( {ω}_{4} - {ω}_{2} ) ,$$

$${ω}_{4} - {ω}_{1} = - ( {ω}_{3} - {ω}_{2} )$$

$$Hence ,$$

$${δ}_{13} = - {δ}_{24} \qquad ( 14 )$$

$${δ}_{14} = - {δ}_{23} \qquad ( 15 )$$

Furthermore, with respect to Equation (12), δᵢⱼ (=ωᵢ−ωⱼ) is antisymmetric with respect to subscripts i and j:

$${δ}_{i j} = - {δ}_{j i} \qquad ( 16 )$$

hᵢⱼ is symmetric with respect to subscripts i, j:

$${h}_{i j} = {h}_{j i} \qquad ( 17 )$$

The coupling constant h₁₂ between the first and second qubits 20-1 and 20-2 coupling to the first electrode 17 (first node) of the coupler 21 via the coupling capacitors 31A and 31B and the coupling constant h₃₄ between the third and fourth qubits 20-3 and 20-4 coupling to the second electrode 18 (second node) of the coupler 21 are approximated to be equal to each other when their resonance angular frequencies are close to each other.

$${h}_{12} = {h}_{34} \qquad ( 18 )$$

The coupling constant h₁₃ between the first and third qubits 20-1 and 20-3 coupled via the coupler 21, the coupling constant h₁₄ between the first and fourth qubits 20-1 and 20-4 coupled via the coupler 21 and the coupling constant h₂₃ between the second and third qubits 20-2 and 20-3 coupled via the coupler 21, and the coupling constant h₂₄ between the second and fourth qubits 20-2 and 20-4 coupled via the coupler 21 are approximated to be equal to each other when their resonance angular frequencies are close to each other.

$${h}_{13} = {h}_{14} = {h}_{23} = {h}_{24} \qquad ( 19 )$$

Under the conditions (14) to (19) above, Equation (12) is, from

$${h}^{( 4 )} = 2 {h}_{12} {h}_{13}^{2} \{ {K}_{1} \frac{- 1}{{δ}_{12} {δ}_{13} {δ}_{14}} + {K}_{2} \frac{1}{{δ}_{12} {δ}_{23} {δ}_{24}} + {K}_{3} \frac{- 1}{{δ}_{13} {δ}_{23} {δ}_{34}} + {K}_{4} \frac{1}{{δ}_{14} {δ}_{24} {δ}_{34}} \} = - 2 {h}_{12} {h}_{13}^{2} ( {K}_{1} \frac{{δ}_{34}}{{δ}_{12} {δ}_{13} {δ}_{14} {δ}_{34}} + {K}_{2} \frac{- {δ}_{34}}{{δ}_{12} {δ}_{13} {δ}_{14} {δ}_{34}} + {K}_{3} \frac{- {δ}_{12}}{{δ}_{12} {δ}_{13} {δ}_{14} {δ}_{34}} + {K}_{4} \frac{{δ}_{12}}{{δ}_{12} {δ}_{13} {δ}_{14} {δ}_{34}} )$$

expressed as follows.

$${h}^{( 4 )} = - 2 {h}_{12} {h}_{13}^{2} \frac{( {K}_{1} - {K}_{2} ) {δ}_{34} + ( {K}_{4} - {K}_{3} ) {δ}_{12}}{{δ}_{12} {δ}_{13} {δ}_{14} {δ}_{34}} \qquad ( 20 )$$

In Equation (20), assuming that the nonlinearity K₁ to K₄ of the first to the fourth qubits 20-1 to 20-4 are all the same,

$${K}_{2} = {K}_{1} , {K}_{3} = {K}_{4} \qquad ( 21 )$$

h⁽⁴⁾ becomes 0 (h⁽⁴⁾=0). In this case, the four-body interaction arising from the nonlinearity of the first and fourth qubits 20-1 to 20-4 is cancelled (turned off).

From Equation (20), by setting the absolute values |K₁−K₂| and |K₄−K₃| to a large value (above a certain value) respectively, and by setting δ₃₄ and δ₁₂ to a large value including a sign, the value (absolute value) of h⁽⁴⁾ becomes large and a large four-body interaction is obtained. For example, if (K₁>K₂ and K₄>K₃) or (K₁<K₂ and K₄<K₃), the difference δ₁₂ (=ω₁−ω₂) between the resonance angular frequencies of the first qubit 20-1 and the second qubit 20-2, and the difference δ₃₄ (=ω₃−ω₄) between the resonance angular frequencies of the third qubit 20-3 and the fourth qubit 20-4 can both be large positive values, or both can be large negative absolute values. That is, ω₁>ω₂ and ω₃>ω₄, or ω₁<ω₂ and ω₃<ω₄.

The resonant frequency is fixed in each qubit 20 of FIG. 3. This resonant frequency is based on, for example, an inductance of the electrode 24 and a capacitance of the capacitor 206 and an inductance and capacitance of the Josephson junction 201 itself, and thus by setting these circuit parameters, for example, w₁>ω₂ and ω₃>ω₄ may be configured.

In each of the qubits 20-1 to 20-4 in FIG. 4, the resonant frequency is variable according to a magnetic flux passing through the loop of the SQUID 210. For this reason, the configuration and circuit parameters of the first to fourth qubits 20-1 to 20-4 are made identical. The first to fourth qubits 20-1 to 20-4 each have a DC bias current applied from a magnetic field application unit (not shown) to each of them can be varied, for example, ω₁>ω₂ and ω₃>ω₄ may be configured. When the DC bias current value is increased, the magnetic flux through the loop of the SQUID 210 of qubit 20 increases.

In Equation (20), when |K₁−K₂| and |K₄−K₃| are set to large values (above a predetermined value), respectively, and K₁>K2 and K₄<K₃, δ₃₄ may be a large positive value and δ₁₂ may be a negative value which is large in an absolute value. Alternatively, δ₃₄ may be set to a negative value which is large in an absolute value and δ₁₂ to a large positive value.

In Equation (20), when |K₁−K₂| and |K₄−K₃| are set to large values (above a predetermined value), respectively, and K₁<K₂ and K₄>K₃, δ₃₄ may be a large negative value and δ₁₂ may be a positive value which is large in an absolute value. Alternatively, δ₃₄ may be set to a large positive value and δ₁₂ to a negative value which is large in an absolute value.

When one of the absolute values |K₂−K₁| and |K₃-K₄| is made larger and the other smaller in Equation (20), there is no need to adjust the difference δ₃₄ in resonance angular frequency between the third qubit 20-3 and the fourth qubit 20-4, the difference δ₁₂ in resonance angular frequency between the first qubit 20-1 and the second qubit 20-2.

Alternatively, in Equation (20), the values of |K₁−K₂| and |K₄−K₃| are set to predetermined values in advance, respectively, and the difference δ₃₄ in the resonance angular frequency between the third qubit 20-3 and the fourth qubit 20-4, and the difference δ₁₂ in the resonance angular frequency between the first qubit 20-1 and the second qubit 20-2, can be adjusted so that h⁽⁴⁾ is set to 0 and the four-body interaction due to the nonlinearity of the qubit 20 is cancelled. In this case, the difference between the resonance frequencies δ₃₄ and δ₁₂ can be adjusted by, for example, reading the frequencies of the first to fourth qubits 20-1 to 20-4 in FIG. 4 from input/output lines (not shown), measuring them with a measuring instrument (not shown) and variably setting the DC bias current from the signal source (not shown) or a microwave current.

By changing the conditions of the four-body interaction of the first to fourth qubits 20-1 to 20-4, the strength of the four-body interaction can be switched even if the first to fourth qubits 20-1 to 20-4 are of the same design.

For example, in Equation (20), the four-body interaction can be made stronger by appropriately adjusting δ₃₄ and δ₁₂ as K₁=K₄>K₂=K₃. That is, Equation (20) is given as the following Equation (22).

$${h}^{( 4 )} = - 2 {h}_{12} {h}_{13}^{2} \frac{( {K}_{1} - {K}_{2} ) ( {δ}_{34} + {δ}_{12} )}{{δ}_{12} {δ}_{13} {δ}_{14} {δ}_{34}} \qquad ( 22 )$$

From Equation (22), when K₁>K₂, the absolute value of h⁽⁴⁾ is made larger, for example, by setting the absolute value of δ₃₄+δ₁₂ to a larger value, and the four-body interaction is made stronger. For example,

$${δ}_{34} + {δ}_{12} = ( {ω}_{3} - {ω}_{4} ) + ( {ω}_{1} - {ω}_{2} ) \qquad ( 23 )$$

Thus, the following condition may be set ω₃>ω₄ and ω₁>ω₂.

Also, the condition for a four-body interaction among the four qubits can be set to

$${ω}_{1} + {ω}_{3} = {ω}_{2} + {ω}_{4} \qquad ( 24 )$$

In this case, from Equation (24),

$${ω}_{1} - {ω}_{2} = - ( {ω}_{4} - {ω}_{3} )$$

$${ω}_{4} - {ω}_{1} = {ω}_{3} - {ω}_{2}$$

### Therefore,

$${δ}_{12} = - {δ}_{34} \qquad ( 25 )$$

$${δ}_{14} = {δ}_{23} \qquad ( 26 )$$

Using Equations (25) and (26) and Equations (18) and (19), Equation (12), from

$${h}^{( 4 )} = 2 {h}_{12} {h}_{13}^{2} \{ {K}_{1} \frac{- 1}{{δ}_{12} {δ}_{13} {δ}_{14}} + {K}_{2} \frac{1}{{δ}_{12} {δ}_{23} {δ}_{24}} + {K}_{3} \frac{- 1}{{δ}_{13} {δ}_{23} {δ}_{34}} + {K}_{4} \frac{1}{{δ}_{14} {δ}_{24} {δ}_{34}} \} = - 2 {h}_{12} {h}_{13}^{2} \{ {K}_{1} \frac{{δ}_{24}}{{δ}_{12} {δ}_{13} {δ}_{14} {δ}_{24}} + {K}_{2} \frac{- {δ}_{13}}{{δ}_{12} {δ}_{14} {δ}_{24} {δ}_{13}} + {K}_{3} \frac{- {δ}_{24}}{{δ}_{13} {δ}_{23} {δ}_{12} {δ}_{24}} + {K}_{4} \frac{{δ}_{13}}{{δ}_{14} {δ}_{24} {δ}_{12} {δ}_{13}} \}$$

can be simplified as follows.

$${h}^{( 4 )} = - 2 {h}_{12} {h}_{13}^{2} \frac{( {K}_{1} - {K}_{3} ) {δ}_{24} + ( {K}_{4} - {K}_{2} ) {δ}_{13}}{{δ}_{12} {δ}_{13} {δ}_{14} {δ}_{24}} \qquad ( 27 )$$

From Equation (27), by setting the absolute values |K₁−K₃| and |K₄−K₂| to large values (above a predetermined value), respectively, and δ₂₄ and δ₁₃ to large values including the sign, the value (absolute value) of h⁽⁴⁾ is made large and thus a large four-body interaction is obtained. For example, when (K₁>K₃ and K₄>K₂) or (K₁<K₃ and K₄<K₂), the difference δ₂₄ (=ω₂−ω₄) in the resonance angular frequency between the second qubit 20-2 and fourth qubit 20-4 and the difference δ₁₃ (=ω₁−ω₃) in the resonance angular frequency between the first qubit 20-1 and the third qubit 20-3 can both be large positive values, or both can be large negative absolute values. That is, ω₂>ω₄ and ω₁>ω₃, or ω₂<ω₄ and ω₁<ω₃.

As control other than the above, various controls described above regarding the non-linear parameters of the qubits and the difference in resonance angular frequency δᵢⱼ between the qubits when the condition for four-body interaction is ω₁+ω₂=ω₃+ω₄ can be applied in the same way by replacing the qubit number 2 as 3 and 3 as 2 in terms of the qubit number, even for ω₁+ω₃=ω₂+ω₄.

Furthermore, the condition for a four-body interaction among the four qubits may be changed to

$${ω}_{1} + {ω}_{4} = {ω}_{2} + {ω}_{3} \qquad ( 28 )$$

In this case, from Equation (28)

$${ω}_{2} - {ω}_{1} = {ω}_{4} - {ω}_{3}$$

$${ω}_{3} - {ω}_{1} = {ω}_{4} - {ω}_{2}$$

### Thus,

$$\begin{matrix}{δ}_{12} = {δ}_{34} & ( 29 ) \\ {δ}_{13} = {δ}_{24} & ( 30 )\end{matrix}$$

Using Equations (29) and (30) and Equations (18) and (19), Equation (12), from

$$\begin{matrix}{h}^{( 4 )} = 2 {h}_{12} {h}_{13}^{2} \{ \begin{matrix}{K}_{1} \frac{- 1}{{δ}_{12} {δ}_{13} {δ}_{14}} + {K}_{2} \frac{1}{{δ}_{12} {δ}_{23} {δ}_{24}} + \\ {K}_{3} \frac{- 1}{{δ}_{13} {δ}_{23} {δ}_{34}} + {K}_{4} \frac{1}{{δ}_{14} {δ}_{24} {δ}_{34}}\end{matrix} \} \\ = - 2 {h}_{12} {h}_{13}^{2} \{ \begin{matrix}{K}_{1} \frac{{δ}_{23}}{{δ}_{12} {δ}_{13} {δ}_{14} {δ}_{23}} + {K}_{2} \frac{- {δ}_{14}}{{δ}_{12} {δ}_{23} {δ}_{13} {δ}_{14}} + \\ {K}_{3} \frac{{δ}_{14}}{{δ}_{13} {δ}_{23} {δ}_{12} {δ}_{14}} + {K}_{4} \frac{- {δ}_{23}}{{δ}_{14} {δ}_{13} {δ}_{12} {δ}_{23}}\end{matrix} \}\end{matrix}$$

can be rewritten as follows.

$${h}^{( 4 )} = - 2 {h}_{12} {h}_{13}^{2} \frac{( {K}_{1} - {K}_{4} ) {δ}_{23} + ( {K}_{3} - {K}_{2} ) {δ}_{14}}{{δ}_{12} {δ}_{13} {δ}_{14} {δ}_{23}} \qquad ( 31 )$$

In Equation (31), if K₁=K₄ and K₂=K₃, h⁽⁴⁾ becomes 0 without adjustment of the difference in resonance frequencies δ₂₃ and δ₁₄ of the first to fourth qubits 20-1 to 20-4, and the four-body interaction due to the nonlinearity of the qubit is cancelled.

In Equation (31), let K₁=K₂ and K₃=K₄, we have

$${h}^{( 4 )} = 2 {h}_{12} {h}_{13}^{2} \frac{( {K}_{4} - {K}_{1} ) ( {δ}_{23} - {δ}_{14} )}{{δ}_{12} {δ}_{13} {δ}_{14} {δ}_{23}} \qquad ( 32 )$$

In Equation (32), when the difference in resonance angular frequencies δ₂₃=δ₁₄, h⁽⁴⁾ is zero and the four-body interaction due to the qubit nonlinearity is cancelled. In Equation (32), with respect to the difference between the resonance angular frequencies δ₂₃ and δ₁₄, for example, if K₄>K₁,

$${δ}_{23} - {δ}_{14} = ( {ω}_{2} - {ω}_{3} ) + ( {ω}_{4} - {ω}_{1} ) > 0 \qquad ( 33 )$$

From, for example, ω₂>ω₃ and ω₄>ω₁, h⁽⁴⁾ becomes a positive value.

In the first to fourth qubits 20-1 to 20-4, the nonlinearity may be changed, for example, by the followings.
(I) In the qubit 20, a plurality of Josephson junctions 201 are connected in series (the number of Josephson junctions to be connected in series may be changed), the configuration (geometrical structure, layout) of the electrodes etc. of the qubit remains the same, but the junction structure (geometry etc.) of the Josephson junctions may be changed.
(II) A structural capacitance inductance of the qubit 20 may be changed.
(III) When the resonance frequency of the qubit 20 is adjustable, its resonance frequency may be changed.

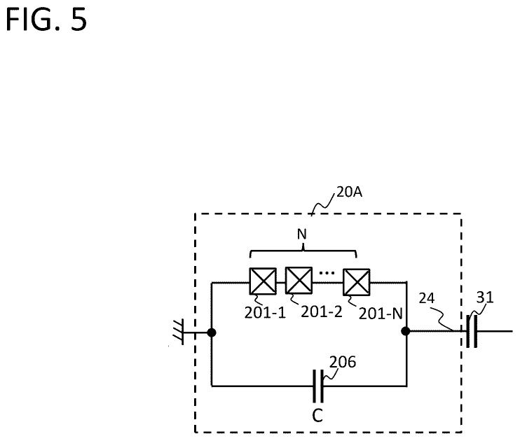

The following describes specific examples of (I) to (III) above.
(I) As an example of connecting a plurality of Josephson junctions in series without changing the structure of electrode 24 of the qubit 20, for example, as shown in FIG. 5 as a qubit 20A,
   N (N>1) Josephson junctions 201-1 to 201-N connected in series, and a capacitor 206 in parallel with the N Josephson junctions 201-1 to 201-N between the electrode 24 and ground may be provided.

When the Josephson junctions are connected in series, the nonlinearity is weakened. When the non-linear parameters are to be different between two qubits 20 in FIG. 3, the number N of Josephson junctions connected in series may be made different from each other in FIG. 5. When the non-linear parameters are to be the same, the number N of Josephson junctions connected in series may be the same. However, when the junction size of each of the N Josephson junctions 201-1 to 201-N in FIG. 5 is the same as the Josephson junction 201 of the qubit 20 in FIG. 3, the resonance frequency will shift from the resonance frequency of the qubit 20 in FIG. 3, and thus the junction size may be adjusted.

For the non-linear parameters K₁ to K₄ of the first to fourth qubits 20-1 to 20-4, in the case of the following setting, as an example,

$${K}_{1} = {K}_{4} > {K}_{2} = {K}_{3} \qquad ( 34 )$$

the second qubit 20-2 and the third qubit 20-3 of FIG. 3 may be configured with the qubit 20A of FIG. 5, and the first qubit 20-1 and the fourth qubit 20-4 may remain the same as the configuration of FIG. 3 (corresponding to N=1 in FIG. 5). Alternatively, the first to fourth qubits 20-1 to 20-4 of FIG. 3 may be configured with the qubit 20A of FIG. 5, and the number of Josephson junctions series-connected in the second qubit 20-2 and the third qubit 20-3 (the same number in the second qubit 20-2 and the third qubit 20-3) may be set greater than the number of Josephson junctions series-connected in the first qubit 20-1 and the fourth qubit 20-4 (the same number in the first qubit 20-1 and the fourth qubit 20-4).

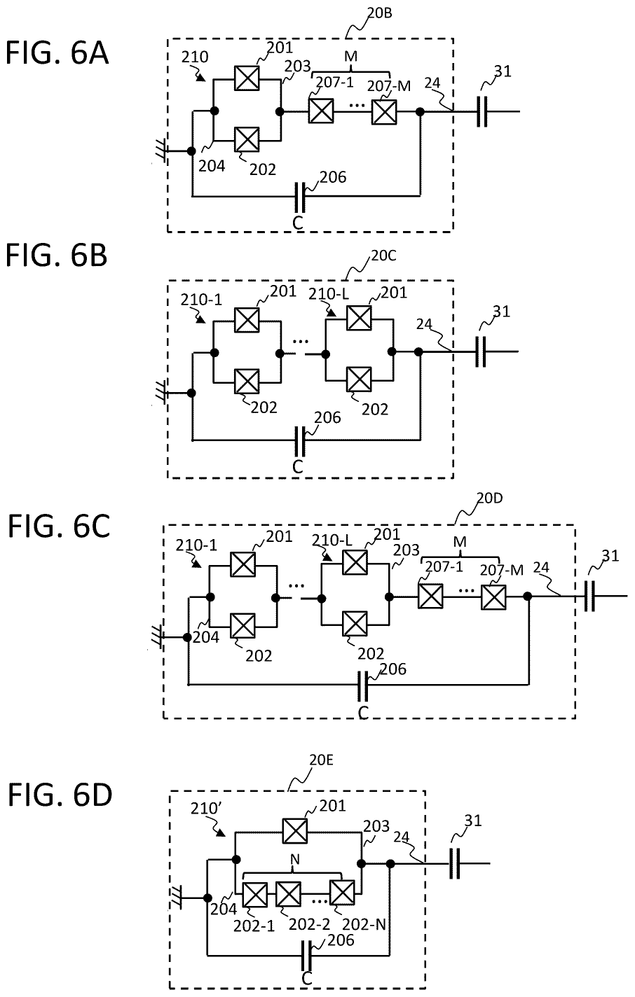

As another example of connecting multiple Josephson junctions in series, there may be provided as shown in FIG. 6A, as a qubit 20B, with the SQUID 210 and M series-connected Josephson junctions 207-1 to 207-M between the electrode 24 and ground. When the Josephson junctions are connected in series, the nonlinearity is weakened. If the nonlinearity of qubit 20B is to be differed, the number M of Josephson junctions 207 connected in series may be differed. As for the non-linear parameters K₁ to K₄ of the first to fourth qubits 20-1 to 20-4, for example, when setting to K₁=K₄>K₂=K₃, the second qubits 20-2 and the third qubit 20-3 in FIG. 4 may be configured with the qubit 20B of FIG. 6A, while the first qubit 20-1 and the fourth qubit 20-4 may be left to be the same as the configuration of FIG. 4. The second qubit 20-2 and the third qubit 20-3 will have smaller nonlinearity than the first qubit 20-1 and the fourth qubit 20-4.

As yet another example of connecting multiple Josephson junctions in series, a configuration with L SQUIDs 210-1 to 210-L connected in series between the electrode 24 and ground may be used, as shown in FIG. 6B, as a qubit 20C. The number L of SQUIDs 210 connected in series may be differed if the nonlinearity of the qubit 20 C is to be differed. For example, when setting to K₁=K₄>K₂=K₃, the second qubit 20-2 and the third qubit 20-3 of FIG. 4 may be configured with the qubit 20C of FIG. 6B, while the first qubit 20-1 and the fourth qubit 20-4 may be left to be the same as the configuration of FIG. 4.

Alternatively, as yet another example of connecting multiple Josephson junctions in series, as shown in FIG. 6C as a qubit 20D, L SQUIDs 210-1 to 210-L are connected in series and M series-connected Josephson junctions 207-1 to 210-M between electrode 24 and ground. When the non-linear parameters of qubit 20D are to be made different, in the qubit 20C in FIG. 6C, at least one of the number L of L series-connected SQUIDs 210-1 to 210-L and the number M of M series-connected Josephson junctions 207-1 to 210-M may be made different. When the non-linear parameters are to be the same between the qubits 20D, the number L of L series-connected SQUIDs 210 and the number M of M series-connected Josephson junctions 207 may be made the same.

Alternatively, as yet another example of connecting a plurality of Josephson junctions in series, as shown in FIG. 6D as a qubit 20E, in a SQUID 210′, N (N≥1) Josephson junctions 202-1 to 202-N connected in series, in parallel with the Josephson junctions 201. When the Josephson junctions are connected in series, the nonlinearity is weakened. As for the non-linear parameters K₁ to K₄ of the first to fourth qubits 20-1 to 20-4, for example, if setting to K₁=K₄>K₂=K₃, the second and third qubits 20-2 in FIG. 4 and qubit 20-3 may be configured with qubit 20E of FIG. 6D, and the first qubit 20-1 and the fourth qubit 20-4 may be left to be the same as the configuration of FIG. 4.

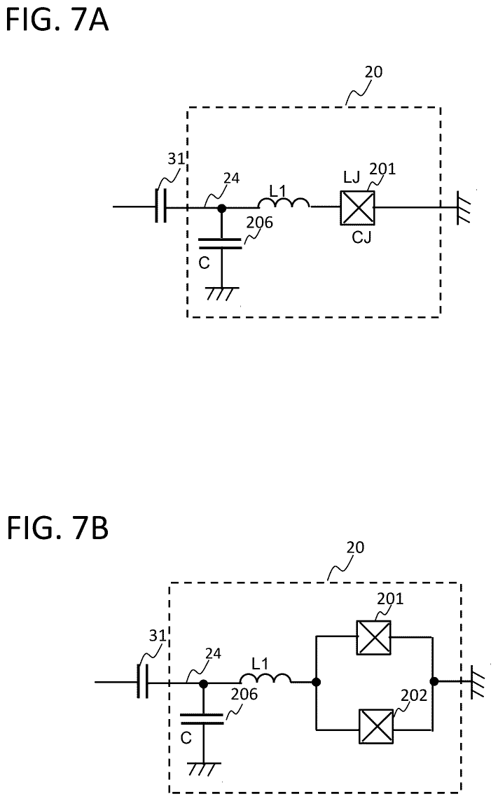

Although not shown, a further variation of FIGS. 6A to 6D is to configure the SQUID 210 of FIG. 6A with the SQUID 210′ of FIG. 6D, and to connect the SQUID 210′ with N series-connected Josephson junctions 202-1 to 202-N between the electrode 24 and ground. Alternatively, the SQUIDs 210-1 to 210-L of FIG. 6B may be configured using the SQUID 210′ of FIG. 6D. The SQUIDs 210-1 to 210-L of FIG. 6C may be configured using the SQUID 210′ of FIG. 6D. In the present disclosure, the qubit 20 is not limited to some of the above variations and may include other combinations with respect to Josephson junctions and SQUIDs.
(II) As a technique for changing the nonlinearity between qubits each including a Josephson junction, the structural capacitance and inductance of the qubit 20 may be changed. FIG. 7A illustrates the structural inductance of the qubit 20 of FIG. 3, as an example. An inductance L1 connected in series with the Josephson junction 201 represents an inductance component of the electrode 24. A capacitance C between the electrode 24 and ground corresponds to a capacitor 206 connected in parallel with the Josephson junction 201. The Josephson junction 201 has its own capacitance C_{J} and a non-linear inductance component L_{J}. Letting a current flowing in the Josephson junction 201 be I, a critical current Ic and Φ₀ is a flux quantum, the non-linear inductance L_{J} of the Josephson junction 201 can be expressed, for example, as follows.

$${L}_{J} = ( \frac{{Φ}_{0}}{2 π {I}_{c}} ) \frac{1}{\sqrt{1 - {( I / {I}_{c} )}^{2}}} \qquad ( 35 )$$

Due to this non-linear inductance L_{J}, the potential energy becomes not-harmonic, each level is no longer spaced at a constant interval and thus a qubit of a two-level system is realized.

FIG. 7B illustrates the structural capacitance and structural inductance using the qubit 20 of FIG. 3 as an example. Referring to FIG. 7B, an inductance L₁ connected in series with the SQUID 210 represents an inductance component of the electrode 24. A capacitance C between electrode 24 and ground corresponds to the capacitor 206 connected in parallel to the SQUID 210. The Josephson junction 201 has its own capacitance component as well as a non-linear inductance component; the structural inductance of the qubit 20 is L₁ and the structural capacitance is 206.

In Equation (9), the nonlinear parameter K₁ (i=1, 2, 3, 4) of the qubit 20 has two main components, one determined by an inductance and the other by a capacitance.

$${K}_{i} = {p}_{i} {E}_{C i} \qquad ( 36 )$$

where E_{ci} is a charged energy of the qubit 20.

pᵢ (Participation ratio) is a ratio of an inductive energy accumulated in the qubit (Josephson junction) to an inductive energy accumulated in the circuit, which can be expressed for example as

$${p}_{i} = \frac{{n}_{iS} {L}_{iS}^{3} + {n}_{iJ} {L}_{iJ}^{3}}{{( {L}_{i L} + {n}_{i S} {L}_{i S} + {n}_{i J} {L}_{i J} )}^{3}} \qquad ( 37 )$$

where,
L_{iL} (i=1, 2, 3, 4) is a structural inductance of the i-th qubit 20-i,
L_{iS} (i=1, 2, 3, 4) is an inductance of a SQUID of the i-th qubit 20-i,
n_{iS} (i=1, 2, 3, 4) is the number of SQUIDs in the i-th qubit 20-i (L in FIGS. 6B and 6C),
L_{iJ} (i=1, 2, 3, 4) s an inductance of Josephson junctions connected in series or connected to the SQUID in the i-th qubit 20-i, and
n_{iJ} (i=1, 2, 3, 4) is the number of Josephson junctions connected in series in the i-th qubit 20-i (M in FIG. 6A, 6C).

The maximum value of pᵢ (i=1, 2, 3, 4) in Equation (37) is 1. To keep pᵢ close to the maximum value, the structural inductance Lᵢ (inductance L1 in FIGS. 7A and 7B) should be as small as possible.

The coupling coefficient K₁ of the four-body interaction by the qubit is basically determined by the structural capacitance Cᵢ of the qubit 20.

$${E}_{C i} = \frac{{e}^{2}}{2 {C}_{i}} \\ ( i = 1 , 2 , 3 , 4 ) \qquad ( 38 )$$

where e is the elementary charge and Cᵢ is an effective structural capacitance of the qubit 20, specifically the capacitance of the capacitor (shunt capacitor) 206 of the i-th qubit 20-i (i=1, 2, 3, 4).

By reducing the capacitance of the capacitor 206, the non-linear parameter Kᵢ (i=1, 2, 3, 4) of the qubit 20-i can be made large, thereby increasing the coupling coefficient h⁽⁴⁾ of the four-body interaction. In this case, the geometrical structure of the qubit 20 electrodes 24 etc. would change, but the nonlinearity can be significantly changed.

Here, the structure of the electrodes of the qubit 20 is changed and when the coupling constant h₁₃ between the first qubit 20-1 and the third qubit 20-3 and the coupling constant h₁₄ between the first qubit 20-1 and the fourth qubit 20-4 are different and the coupling constant h₁₃ between the first qubit 20-1 and the third qubit 20-3 and the coupling constant h₂₃ between the second qubit 20-2 and the third qubit 20-3 are different, Equation (19) does not hold and from Equation (12) above, we have the following.

$$\begin{matrix}{h}^{( 4 )} = - 2 ( \begin{matrix}{K}_{1} \frac{{h}_{21}}{{δ}_{12}} \frac{{h}_{31}}{{δ}_{13}} \frac{{h}_{41}}{{δ}_{14}} + {K}_{2} \frac{- {h}_{12}}{{δ}_{12}} \frac{{h}_{32}}{{δ}_{23}} \frac{{h}_{42}}{{δ}_{24}} + \\ {K}_{3} \frac{{h}_{13}}{{δ}_{13}} \frac{{h}_{23}}{{δ}_{23}} \frac{{h}_{43}}{{δ}_{34}} + {K}_{4} \frac{- {h}_{14}}{{δ}_{14}} \frac{{h}_{24}}{{δ}_{24}} \frac{{h}_{34}}{{δ}_{34}}\end{matrix} ) \\ = - 2 {h}_{12} {h}_{13} ( \begin{matrix}{K}_{1} \frac{{h}_{14} {δ}_{34}}{{δ}_{12} {δ}_{13} {δ}_{14} {δ}_{34}} + {K}_{2} \frac{- {h}_{23} {δ}_{34}}{{δ}_{12} {δ}_{13} {δ}_{14} {δ}_{34}} + \\ {K}_{3} \frac{- {h}_{23} {δ}_{12}}{{δ}_{12} {δ}_{13} {δ}_{14} {δ}_{34}} + {K}_{4} \frac{{h}_{14} {δ}_{12}}{{δ}_{12} {δ}_{13} {δ}_{14} {δ}_{34}}\end{matrix} ) \\ = 2 {h}_{12} {h}_{13} \{ \frac{- {h}_{14} ( {K}_{1} {δ}_{34} + {K}_{4} {δ}_{12} ) + {h}_{23} ( {K}_{2} {δ}_{34} + {K}_{3} {δ}_{12} )}{{δ}_{12} {δ}_{13} {δ}_{14} {δ}_{34}} \}\end{matrix} \qquad ( 39 )$$

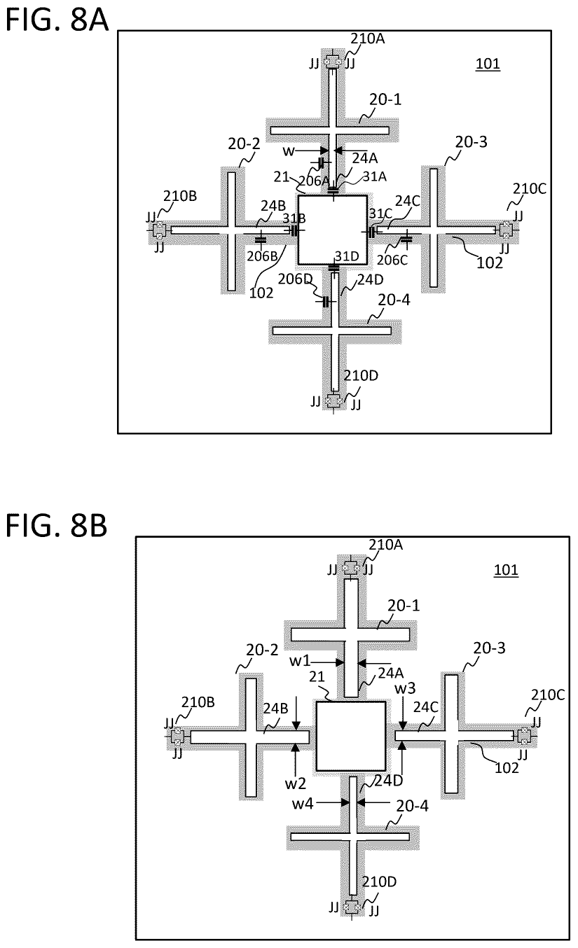

FIG. 8A is a schematic plan view illustrating part of a wiring layer of a quantum chip. A non-limiting example of a pattern shape of the qubits 20 is schematically shown in FIG. 8A. The electrodes 24A-24D of the first to fourth qubits 20-1 to 20-4 have a cross-shaped electrode structure with four arms extended in four directions from a center and surrounded by a ground plane 101 via a gap 102. The gap 102 between the electrodes 24A-24D and the ground plane 101 constitutes a capacitance component of the capacitor 206. The gap 102 is not provided with a ground or wiring pattern and the substrate surface of the quantum chip is exposed. A tip of one of the four arms of each electrode 24A-24D is capacitively coupled via gap 102 with coupler 21 as a coupler connection portion. The gap 102 between the tip of the arm of each electrode 24A-24D that is opposite the electrode of the coupler 21 (not shown) and the electrode of the coupler 21 (not shown) constitutes the capacitance of the coupling capacitors 31A-31D.

In the example of FIG. 8A, the electrodes 24A-24D of each of the first to fourth qubits 20-1 to 20-4 have the same shape. SQUIDs 210A to 210D are bridged between each of the electrodes 24A to 24D of each of the first to fourth qubits 20-1 to 20-4 and the opposing ground plane 101. In the example of FIG. 8A, for simplicity, the SQUIDs 210A-210D are connected in the cross-shaped electrodes 24A-24D of each of the first to fourth qubits 20-1 to 20-4 to the end of the arm opposite to the arm coupling to the coupler 21 and the ground plane 101 opposite thereto, but it may also be connected between one of the longitudinal sides of the arm and the ground plane 101 opposite thereto. For example, when the tip of each arm of the cross-shaped electrodes 24A-24D is coupled to a different coupler 21, the SQUID 210 is connected between an edge of the arm and the ground plane 101 opposite thereto. In FIG. 8A, in the first to fourth qubits 20-1 to 20-4, the SQUIDs 210A to 210D may be Josephson junctions 201A to 201D, as shown in FIG. 3. The electrode structure of the qubits 20 is of course not limited to the cross-shaped shape of FIG. 8A which shows a non-limiting example.

FIG. 8B illustrates an example of changing the geometry of the structural inductance and structural capacitance of the qubits, and an example of changing the structure of the electrodes 24 of the qubits of the first to fourth qubits 20-1 to 20-4 from that of FIG. 8A. In FIG. 8B, capacitors 206A-206D and coupling capacitors 31A-31D shown in FIG. 8A are not shown. FIG. 8B shows that the first qubit 20-1 and the fourth qubit 20-4 differ in the width W1 of the arm of electrode 24A and the width W4 of the arm of electrode 24D, while the second qubit 20-2 and the third qubit 20-3 differ in the width W2 of the arm of electrode 24B and the width W3 of the arm of electrode 24C. When the width W of the arm of electrode 24 is wider and the gap (slot width) with the ground plane is narrower, the capacitance (structural capacitance) of the capacitor 206 between electrode 24 and the ground is also different. In FIG. 8B, the widths W1 to W4 of the arms of the electrodes 24A to 24D of the first qubits 20-1 to the fourth qubits 20-4 are different from each other for the sake of explanation, but one of the first 20-1 to 20-4 qubits may differ from the electrodes of the other qubits in terms of arm width, arm length, etc. The capacitance (structural capacitance) of capacitors 206A and 206D between electrode 24A and ground and between electrode 24D and ground are different between the first qubit 20-1 and the fourth qubit 20-4. The configuration change of the geometry of electrode the structure ma y change inductance components of electrodes 24A and 24D.

In the first qubit 20-1 and the third qubit 20-3, the capacitances of the capacitors 206A and 206C between electrode 24A and ground and between electrode 24C and ground are different, and the inductance components of electrodes 24A and 24C are also different. As a result, the coupling h₁₃ between the first qubit 20-1 and the third qubit 20-3 (the third qubit 20-3) differs from the coupling h₁₄ between the first qubit 20-1 and the fourth qubit 20-4 (which differs from the electrode structure of the third qubit 20-3). The coupling his between the first qubit 20-1 and the third qubit 20-3 is also different from the coupling h₂₃ between the second qubit 20-2 (different electrode structure from the first qubit 20-1) and the third qubit 20-3. The configuration in FIG. 8B corresponds to Equation (39) above. The electrode structure of qubit 20 is of course not limited to the cross-shaped shape of FIG. 8B, which shows a non-limiting example.

In the examples of FIGS. 8A and 8B, a substrate of the quantum chip is, for example, silicon (Si), but other electronic materials such as sapphire or compound semiconductor materials (Group IV, III-V, II-VI) may be used. The substrate of the quantum chip is preferably be monocrystalline, but may also be polycrystalline or amorphous. Pattern of the wiring layer of the quantum chip may be formed by deposition (vapor-deposition) of a superconducting material on the surface of the substrate and patterning thereof. For example, niobium (Nb) or aluminium (aluminum) (Al) may be used as the superconducting material (wiring material) for the wiring and electrodes in the wiring layer of the quantum chip, but is not limited thereto. Niobium nitride, indium (In), lead (Pb), tin (Sn), rhenium (Re), palladium (Pd), titanium (Ti), titanium nitrides, molybdenum (Mo), tantalum (Ta), tantalum nitrides, and any alloy including at least one of these, that is, any metal may be used that becomes superconducting when cooled to an extremely low temperature. As a non-limiting example, a Josephson junction (Al/AlOₓ/Al) may be formed by forming a tunnel oxide film (AlOₓ) by forming and oxidizing a first aluminium film on the surface of the quantum chip substrate by oblique deposition and forming a second aluminium film by oblique deposition from the opposite direction to the previous one.
(III) In case where the qubit 20 is frequency tunable, the resonance angular frequency is changed. In the example shown in FIG. 4, when the first to fourth qubits 20-1 to 20-4 include SQUIDs 210A to 210D, respectively, and each resonance frequency thereof is adjustable, the resonance angular frequencies ω₁ to ω₄ of the first to fourth qubits 20-1 to 20-4 may be changed. For example, referring to FIG. 8A, in the SQUIDs 210A to 210D of the first to fourth qubits 20-1 to 20-4 are provided magnetic field application units (not shown) close to the first to fourth qubits 20-1 to 20-4 and the resonance frequencies of the first to fourth qubits 20-1 to 20-4 are adjusted by changing the magnetic flux applied to the SQUIDs 210A to 210D, respectively, from the magnetic field application units (not shown). In this case, the nonlinearity of the qubits does not change extremely, and from Equation (8), the value of the coupling coefficient h⁽⁴⁾ of the four-body interaction due to the nonlinearity of the qubits 20 does not change extremely. However, if there is a frequency region where the value of the coupling coefficient of the four-body interaction h⁽⁴⁾ due to the nonlinearity of qubits changes relatively well as the resonance frequency (operating point) of each of the first to fourth qubits 20-1 to 20-4, then it is also possible to make the coupling coefficient of the four-body interaction h⁽⁴⁾ large for the first to fourth qubits 20-1 to 20-4 of the same design (same layout), by selecting this frequency region. In FIG. 8A, the structure of electrodes 24A-24D and Josephson junctions 201A-201D of the first to fourth qubits 20-1 to 20-4 are the same, but the magnetic flux applied to each loop of SQUID 210A-210D is changed (see FIG. 8B). By changing the magnetic flux applied (changing the DC current value flowing in the magnetic flux generator), the resonance frequency of the first to fourth qubits 20-1 to 20-4 can be varied.

In Equation (22) of h⁽⁴⁾, in the case of K₁=K₄>K₂=K₃, when adjusting the difference in the resonance angular frequency between the third qubit 20-3 and the fourth qubit 20-4 in FIG. 4, δ₃₄ (=ω₃−ω₄), and the difference in the resonance angular frequency between the first qubit 20-1 and the second qubit 20-2 δ₁₂ (=ω₁−ω₂), the magnetic flux applied to the first and fourth SQUIDs 210A to 210D in FIG. 8A may be changed.

It is, as a matter of course, possible to combine two or three of the above (I) through (III), rather than selecting any one of the above (I) through (III), as a control of the four-body interaction due to the nonlinearity of the qubits 20.

In the above, description is made to the coupling coefficient h⁽⁴⁾ of the four-body interaction by the first to the fourth qubits 20-1 to 20-4, but a many-body interaction (three-body interaction, five to eight-body interaction, etc.) can be caused to exhibit in the same way for three or more qubits.

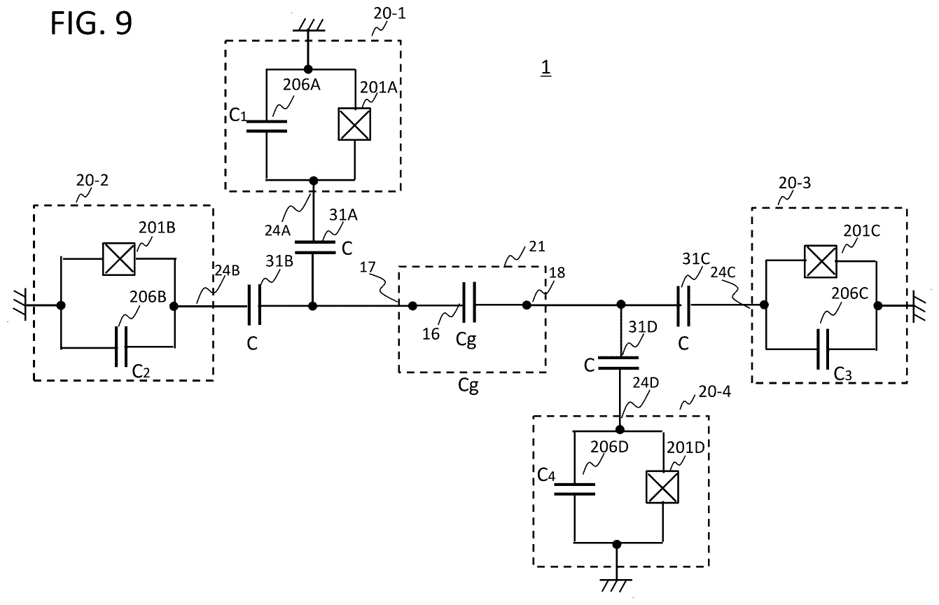

FIG. 9 illustrates one of the variations of FIG. 3. Referring to FIG. 9, the coupler 21 includes a capacitor 16 connected between the first electrode (first node) 17 and the second electrode 18 (second node). The capacitor 16 may include a capacitance of a gap between the first electrode (first node) 17 and the second electrode 18 (second node). In this case, the capacitor 16 may be configured as an interdigital capacitor in which the opposing first electrode 17 and second electrode 18 are each arranged in a nested manner with protrusions on the opposite side.

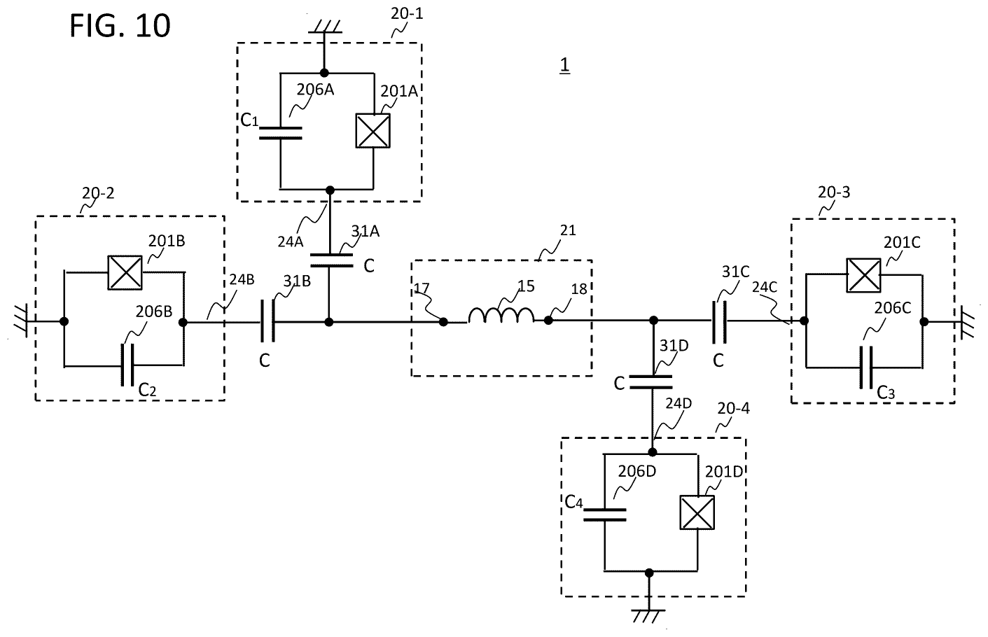

FIG. 10 illustrates one of the variations of FIG. 3. Referring to FIG. 10, the coupler 21 is configured to include an inductor 15 between the first electrode (node) 17 and the second electrode (node) 18. The inductor 15 may be made up of a coplanar wave guide wired in a meander shape between the first electrode (node) 17 and the second electrode (node) 18.

In the case of the examples in FIGS. 9 and 10, as in the example in FIG. 3, any of the above methods (I) through (III), or a combination of at least two of them, may be used to make the nonlinearity of at least one of the four qubits 20 different from the nonlinearity of the other qubits.

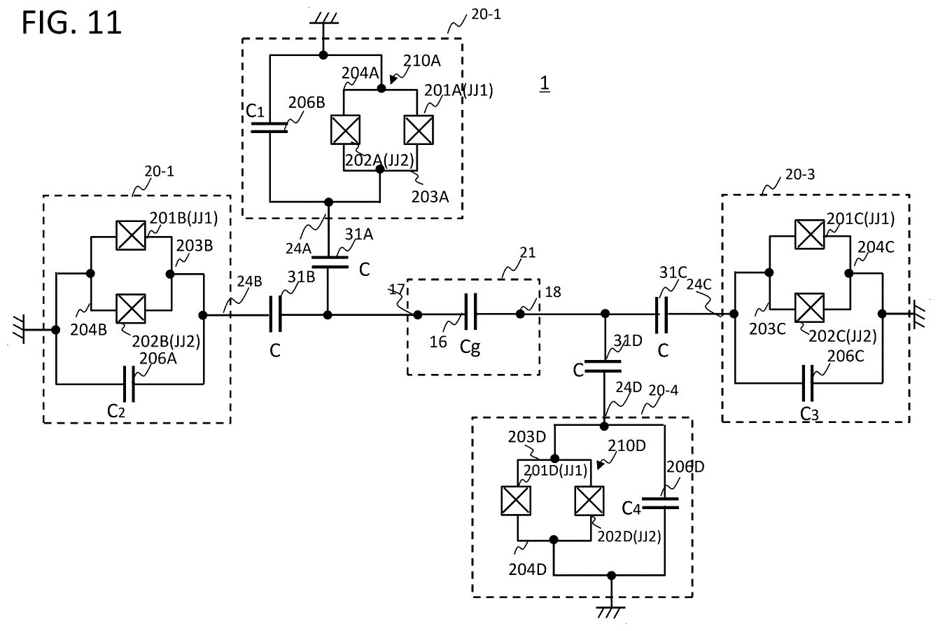

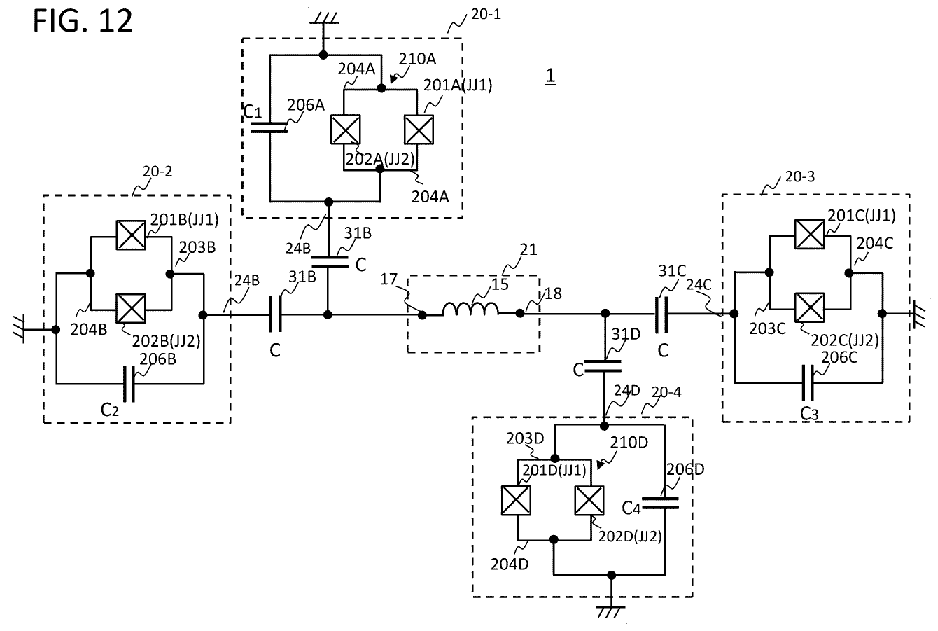

FIGS. 11 and 12 illustrate variations of FIG. 4 (where qubit 20 has a SQUID 210), where the coupler 21 is made up of a capacitor 16 and an inductor 15. In the case of the examples in FIGS. 11 and 12, as in the example in FIG. 4, the nonlinearity of at least one of the four qubits 20 may be made different from that of the other qubits by using the methods (I) through (III) described above, or a combination of at least two of these. In FIG. 12, the number of Josephson junctions to be connected in series and at least one of the structural inductance and structural capacitance may be made identical among the first and fourth qubits 20-1 to 20-4, and the resonance frequency thereof may be varied by making magnetic fluxes respectively penetrating SQUID 210A-210D different.

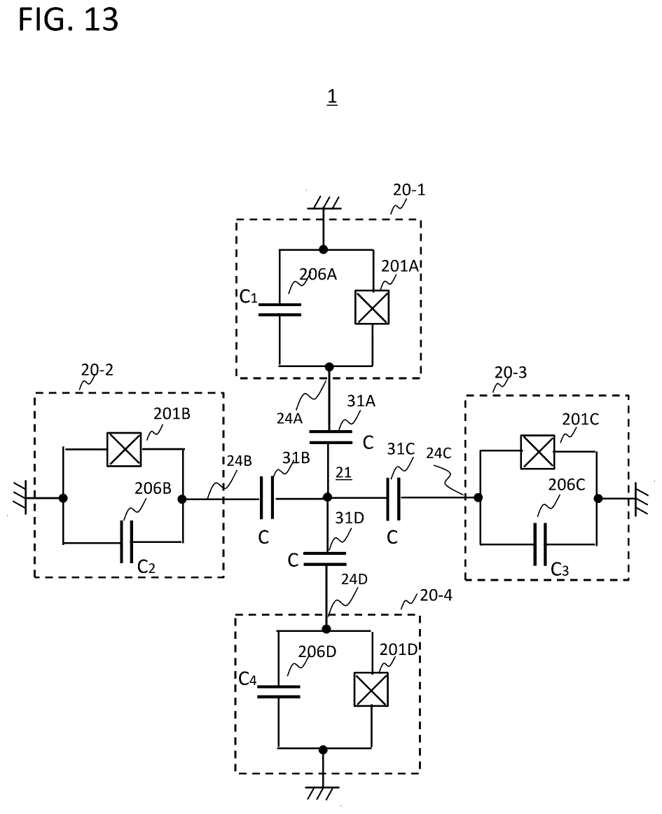

FIG. 13 illustrates one of the variations of FIG. 3. Referring to FIG. 13, the first and second qubits 20-1 and 20-2 are coupled through coupling capacitors 31A and 31B, respectively, and the third and fourth qubits 20-3 and 20-4 are coupled through connected to a common node via capacitors 31C and 31D.

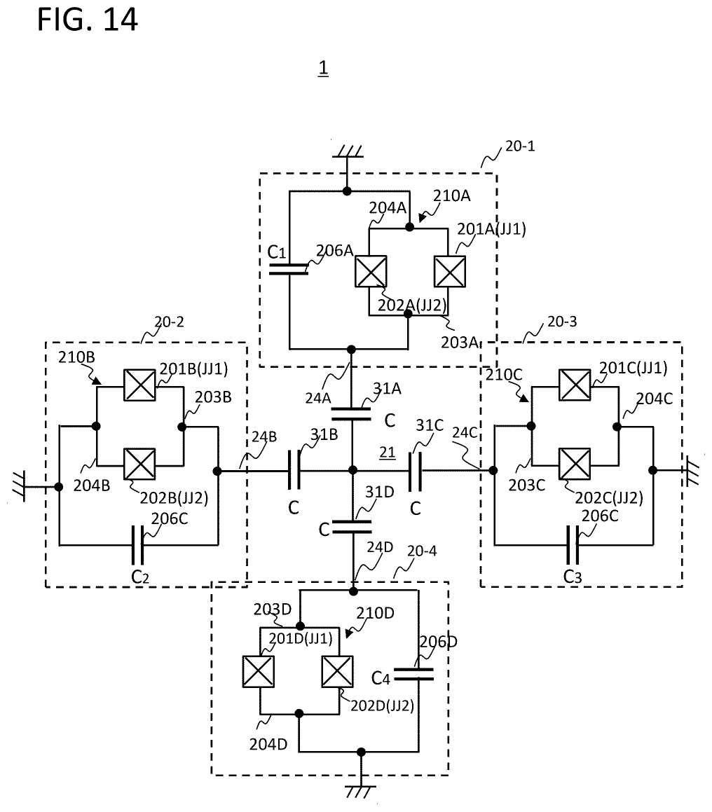

FIG. 14 illustrates one of the variations of FIG. 4. Referring to FIG. 14, the first and second qubits 20-1 and 20-2 are connected via coupling capacitors 31A and 31B, respectively, and the third and fourth qubits 20-3 and 20-4 are connected via coupling connected to a common node via capacitors 31C and 31D. In FIGS. 13 and 14, the node to which the four qubits 20-1 to 20-4 are commonly connected via coupling capacitors 31A to 31D may be referred to as the coupler 21.

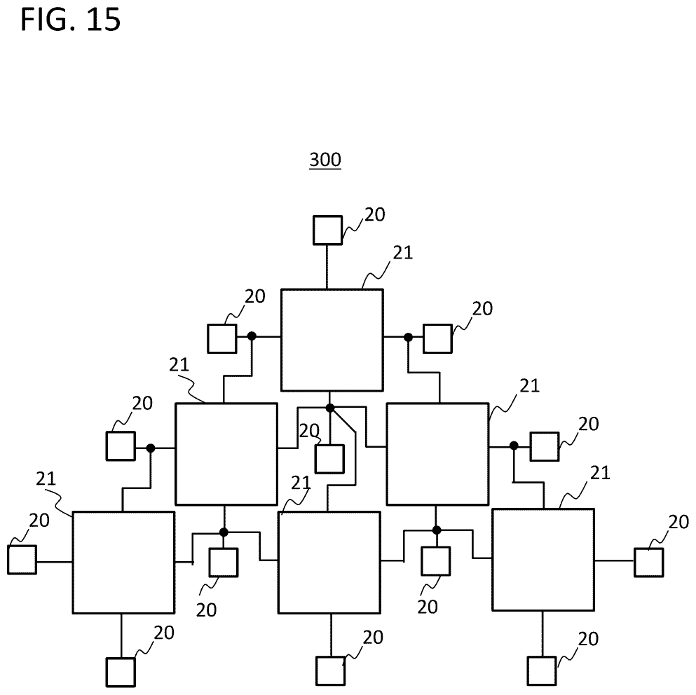

FIG. 15 schematically illustrates a n example configuration of a superconducting quantum computer 300 (quantum annealing machine). In the example of FIG. 15, each coupler 21 couples four adjacent qubits 20 with a four-body interaction. The coupler 21 and the four qubits 20 adjacent to it are referred to as a unit structure (also referred to as a Plaquette). In the superconducting quantum computer 300, at least one qubit 20 is connected to a plurality of couplers 21. In the example shown in FIG. 15, the superconducting quantum computer 300 has multiple unit structures and the qubit 20 is shared by multiple unit structures. In the example shown in FIG. 15, 13 qubits 20 are integrated, but any number of qubits may be integrated in a similar manner. The signal source and readout are omitted in FIG. 15. The configuration shown in FIG. 15 is suitable for LHZ (Lechner, Hauke, Zoller) network, which is one of the quantum annealing methods.

In the present disclosure, couplers, etc., are not limited to lump ed constant circuits (e.g., superconducting LC resonators), but can also be applied to distributed constant types (e.g., coplanar superconducting transmission line resonators).
Reference Literature 1: Wolfgang Lechner, Philipp Hauke, and Peter Zoller, “A quantum annealing architecture with all-to-all connectivity from local interactions”, SCIENCE ADVANCES 23 Oct. 2015 Vol 1, Issue 9

Examples/embodiments disclosed above are annexed as follows (but not limited thereto).
(Note 1) A quantum circuit apparatus includes a coupler including one or more linear elements and at least three or more qubits coupled in many-body interaction via the coupler, wherein at least one qubit out of the at least three or more qubits has a nonlinearity different from that of one or more other qubits.
(Note 2) In the quantum circuit apparatus of Note 1, the many-body interaction is a four-body interaction among four qubits.
(Note 3) In the quantum circuit apparatus of Note 1 or 2, the coupler includes a capacitor and/or an inductor as a linear element.
(Note 4) In the quantum circuit apparatus of any one of Notes 1 to 3, the qubit includes at least one Josephson junction and a capacitor connected in parallel between an electrode and ground.
(Note 5) In the quantum circuit apparatus of any one of Notes 1 to 3, the qubit includes a SQUID (Superconducting Quantum Interference Device) including a plurality of Josephson junctions in a loop and a capacitor.
(Note 6) In the quantum circuit apparatus of any one of Notes 1 to 5, the qubit is capacitively coupled to the coupler.
(Note 7) In the quantum circuit apparatus of any one of Notes 1 to 6, when focusing on one of the four qubits, letting h denote a coupling strength between one qubit and other qubit,
δ denote a difference between a resonance frequency of the one qubit and a resonance frequency of the other qubit, and
K_{q} denote a parameter representing a nonlinearity of the one qubit,
the coupling coefficient h⁽⁴⁾ of the four-body interaction by the four qubits includes a term (h/δ)³ K_{q}.
(Note 8) In the quantum circuit apparatus of Note 7, the coupling coefficient h⁽⁴⁾ of the four-body interaction of the four qubits is given as,

$${h}^{( 4 )} = 2 {\sum }_{i = 1}^{4} {\prod }_{{j = 1}_{( j \neq i )}}^{4} [ ( \frac{{h}_{i j}}{{δ}_{j i}} ) {K}_{i} ] \qquad ( 4 )$$

where hᵢⱼ is the strength of the coupling between i-th qubit and j-th qubit (i,j=1, . . . , 4 but j≠i),
δⱼᵢ is the difference ωⱼ−ωᵢ between the resonance angular frequencies ωⱼ and ωᵢ of the j-th qubit and the i-qubit (i,j=1, . . . , 4, j #i), and
K₁ (i=1, . . . , 4) is a parameter representing nonlinearity of the ith qubit.
(Note 9) In the quantum circuit apparatus of Notes 2 to 8, with respect to a condition of the four-body interaction by the first to fourth resonance angular frequencies ω₁, ω₂, ω₃ and ω₄ of the first to fourth qubits of the four qubits

$${ω}_{1} + {ω}_{1} = {ω}_{m} + {ω}_{n}$$

where l, m and n are such that
for l=2, m and n are 3 and 4 respectively;
for l=3, m and n are 2 and 4 respectively; and
for l=4, m and n are 2 and 3 respectively,
the coupling coefficient h⁽⁴⁾ of the four-body interaction by the four qubits is determined by
a difference between the nonlinear parameter K₁ of the first qubit and the nonlinear parameter K₁ of the l-th qubit;
a difference between the nonlinear parameter Kₙ of the nth qubit and the nonlinear parameter Kₘ;
a difference δ₁₁=ω₁−ω₁ between a resonance angular frequency ω₁ of the first qubit and a resonance angular frequency ω₁ of the 1-th qubit; and
a difference δₙₘ=ωₙ−ωₘ between a resonance angular frequency ωₙ of the n-th qubit and a resonance angular frequency ωₘ of the m-th qubit.
(Note 10) In the quantum circuit apparatus of Note 9, when the condition of the four-body interaction is ω₁+ω₂=ω₃+ω₄,
an absolute value of a difference between the nonlinear parameters K₁ and K₂ of said first and second qubits and an absolute value of a difference between the nonlinear parameters K₃ and K₄ of the third and fourth qubits are made each greater than a predetermined value, or
out of an absolute value of a difference between the nonlinear parameters K₁ and K₂ of the first and second qubits and an absolute value of a difference between the nonlinear parameters K₃ and K₄ of the third and fourth qubits, one of which is greater and the other is less.
(Note 11) In the quantum circuit apparatus of Note 9, when the condition of said four-body interaction is ω₁+ω₂=ω₃+ω₄,
the nonlinear parameters K₁ and K₄ of the first and fourth qubits are made identical,
the nonlinear parameters K₂ and K₃ of the second and third qubits are made identical, and
the nonlinear parameter K₂ of the second qubit is made greater than the nonlinear parameter K₁ of the first qubit.
(Note 12) In the quantum circuit apparatus of Note 9, when the condition of the four-body interaction is ω₁+ω₂=ω₃+ω₄, the strength of the coupling between at least one of the four qubits and another qubit is different from that between the first qubit and yet another qubit.
(Note 13) In the quantum circuit apparatus of Note 4, the number of Josephson junctions connected in series in the at least one qubit is made different from that of one or more other qubits.
(Note 14) In the quantum circuit apparatus of Note 5, the number of SQUIDs connected in series in the at least one qubit is made different from that of one or more other qubits.
(Note 15) In the quantum circuit apparatus of any one of Notes 1 to 14, at least one of the number of series-connected SQUIDs and the number of series-connected Josephson junctions in the at least one qubit is different from that of one or more other qubits.
(Note 16) In the quantum circuit apparatus of Note 1-15, a value of a structural inductance and/or capacitance in the at least one qubit is made different from that of one or more other qubits.
(Note 17) In the quantum circuit apparatus of any one of Notes 1-16, the resonance frequency of the at least one qubit is made different from that of one or more other qubits.
(Note 18) A method for controlling a strength of coupling in which at least first to third qubits are coupled with a many-body interaction via a coupler,
   constituting the coupler with one or more linear elements; and
   making a nonlinearity of at least one of the first through third qubits different from that of one or more other qubits.
(Note 19) In the control method of Note 18, the many-body interaction is a four-body interaction among four qubits.
(Note 20) In the control method of Notes 18 or 19, the coupler includes a capacitor and/or an inductor as a linear element.

The disclosures in Non-Patent Literature 1 and Reference Literature 1 above shall be incorporated herein by reference. Within the framework of the entirety of the preen disclosure invention (including the scope according to claims), based on the basic technical concept, changes and adjustments to the embodiments or examples are possible. In addition, various combinations and selections of various disclosed elements (including each element of each Note, each element of each example, each element of each drawing, etc.) are possible within the framework of the claimed subject matters of the present disclosure. That is, the present disclosure includes, as a matter of course, various transformations and modifications that a person skilled in the art would be able to make in accordance with the entire disclosure including the claims and the technical concept.

What is claimed is:

1. A quantum circuit apparatus comprising:
a coupler made up of one or more linear elements; and
at least three or more qubits coupled with a many-body interaction via the coupler,
wherein at least one qubit out of the at least three or more qubits has a nonlinearity different from that of one or more other qubits.

2. The quantum circuit apparatus according to claim 1, wherein the many-body interaction is a four-body interaction by four qubits.

3. The quantum circuit apparatus according to claim 1, wherein the one or more linear elements of the coupler includes
a capacitor and/or an inductor.

4. The quantum circuit apparatus according to claim 1, wherein the qubit includes:
a Josephson junction; and
a capacitor.

5. The quantum circuit apparatus according to claim 1, wherein the qubit includes
a SQUID (Superconducting Quantum Interference Device) including a plurality of Josephson junctions in a loop; and
a capacitor.

6. The quantum circuit apparatus according to claim 2, wherein the qubit is capacitively coupled to the coupler.

7. The quantum circuit apparatus according to claim 2, wherein a coupling coefficient h⁽⁴⁾ of the four-body interaction by the four qubits is given as,
$${h}^{( 4 )} = 2 {\sum }_{i = 1}^{4} {\prod }_{{j = 1}_{( j \neq i )}}^{4} [ ( \frac{{h}_{i j}}{{δ}_{j i}} ) {K}_{i} ]$$
where hᵢⱼ is the strength of the coupling between i-th qubit and j-th qubit (i,j=1, . . . , 4 but j≠i),
δⱼᵢ is the difference ωⱼ−ωᵢ between the resonance angular frequencies ωⱼ and ωᵢ of the j-th qubit and the i-qubit (i,j=1, . . . , 4, j≠i), and
Kᵢ (i=1, . . . , 4) is a parameter representing nonlinearity of the i-th qubit.

8. The quantum circuit apparatus according to claim 2, wherein respect to a condition of the four-body interaction by the first to fourth resonance angular frequencies ω₁, ω₂, ω₃ and ω4 of the first to fourth qubits of the four qubits
$${ω}_{1} + {ω}_{1} = {ω}_{m} + {ω}_{n}$$
where l, m and n are such that
for l=2, m and n are 3 and 4 respectively;
for l=3, m and n are 2 and 4 respectively; and
for l=4, m and n are 2 and 3 respectively,
the coupling coefficient h⁽⁴⁾ of the four-body interaction by the four qubits is determined by set values including:
a difference between the nonlinear parameter K₁ of the first qubit and the nonlinear parameter K₁ of the 1-th qubit;
a difference between the nonlinear parameter Kₙ of the nth qubit and the nonlinear parameter Kₘ;
a difference δ₁₁=ω₁−ω₁ between a resonance angular frequency ω₁ of the first qubit and a resonance angular frequency ω₁ of the l-th qubit; and
a difference δₙₘ=ωₙ−ωₘ between a resonance angular frequency on of the n-th qubit and a resonance angular frequency ωₘ of the m-th qubit.

9. The quantum circuit apparatus according to claim 1, wherein the number of Josephson junctions connected in series and/or the number of SQUIDs connected in series in the at least one qubit is different from the other qubits.

10. The quantum circuit apparatus according to claim 1, wherein a value of a structural inductance and/or capacitance in the at least one qubit is made different from that of one or more other qubits.

11. A method for controlling a strength of coupling in which at least first to third qubits are coupled with a many-body interaction via a coupler, the method comprising:
constituting the coupler with one or more linear elements; and
making a nonlinearity of at least one of the first through third qubits different from that of one or more other qubits.

12. The method according to claim 11, wherein the many-body interaction is a four-body interaction by four qubits.
